(19) United States
(12) Patent Application Publication
(10) Pub. No.: US 2025/0022946 A1
(43) Pub. Date: Jan. 16, 2025

(54) SEMICONDUCTOR DEVICE STRUCTURE AND METHOD FOR FORMING THE SAME

(71) Applicant: Taiwan Semiconductor Manufacturing Company, Ltd., Hsinchu (TW)

(72) Inventors: Ta-Chun LIN, Hsinchu (TW); Jhon-Jhy LIAW, Zhudong Township (TW)

(73) Assignee: Taiwan Semiconductor Manufacturing Company, Ltd., Hsinchu (TW)

(21) Appl. No.: 18/350,992

(22) Filed: Jul. 12, 2023

(51) Int. Cl. H01L 29/775; H01L 21/8234; H01L 27/088; H01L 29/06; H01L 29/417; H01L 29/423

(52) U.S. Cl. CPC H01L 29/775; H01L 21/823475; H01L 21/823481; H01L 27/088; H01L 29/0673; H01L 29/41775; H01L 29/42392

(57) ABSTRACT

A method for forming a semiconductor device structure includes forming fin structures over a substrate. The method also includes depositing an isolation material surrounding the fin structures. The method also includes forming a dummy gate structure across the fin structure. The method also includes growing source/drain epitaxial structures over opposite sides of the dummy gate structure. The method also includes removing the dummy gate structure. The method also includes recessing the isolation material after removing the dummy gate structure. The method also includes forming a gate structure over the isolation material.

### BACKGROUND

Semiconductor devices are used in a variety of electronic applications, such as personal computers, cell phones, digital cameras, and other electronic equipment. Semiconductor devices are typically fabricated by sequentially depositing insulating or ILD structures, conductive layers, and semiconductive layers of material over a semiconductor substrate, and patterning the various material layers using lithography to form circuit components and elements thereon. Many integrated circuits are typically manufactured on a single semiconductor wafer, and individual dies on the wafer are singulated by sawing between the integrated circuits along a scribe line. The individual dies are typically packaged separately, in multi-chip modules, for example, or in other types of packaging.

Recently, multi-gate devices have been introduced in an effort to improve gate control by increasing gate-channel coupling, reduce OFF-state current, and reduce short-channel effects (SCEs). One such multi-gate device that has been introduced is the gate-all around transistor (GAA). The GAA device gets its name from the gate structure which can extend around the channel region providing access to the channel on two or four sides. GAA devices are compatible with conventional complementary metal-oxide-semiconductor (CMOS) processes.

However, it can be challenging to integrate the fabrication of GAA features around the nanowire. While current methods have been satisfactory in many respects, continued improvements are still needed.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a perspective representation of a semiconductor device structure, in accordance with some embodiments of the disclosure.

FIGS. 2A-1, 2A-2, 2A-3, 2B-1, 2B-2, 2B-3, 2B-4, 2B-5, 2C-1, 2C-2, 2C-3, 2C-4, 2C-5, 2D-1, 2D-2, 2D-3, 2D-4, 2D-5, 2E-1, 2E-2, 2E-3, 2E-4, 2E-5, 2F-1, 2F-2, 2F-3, 2F-4, 2F-5, 2G-1, 2G-2, 2G-3, 2G-4, 2G-5, 2H-1, 2H-2, 2H-3, 2H-4 and 2H-5 are cross-sectional representations of various stages of forming a semiconductor device structure, in accordance with some embodiments of the disclosure.

FIGS. 3A-1, 3A-2, 3A-3, 3B-1, 3B-2, 3B-3, 3C-1, 3C-2, 3C-3, 3C-4, 3C-5, 3D-1, 3D-2, 3D-3, 3D-4 and 3D-5 are cross-sectional representations of various stages of forming a semiconductor device structure, in accordance with some embodiments of the disclosure.

FIGS. 4A-1, 4A-2, 4A-3, 4A-4, 4A-5, 4B-1, 4B-2, 4B-3, 4B-4, 4B-5, 4C-1, 4C-2, 4C-3, 4C-4 and 4C-5 are cross-sectional representations of various stages of forming a semiconductor device structure, in accordance with some embodiments of the disclosure.

FIGS. 5A-1, 5A-2, 5A-3, 5A-4, 5A-5, 5B-1, 5B-2, 5B-3, 5B-4, 5B-5, 5C-1, 5C-2, 5C-3, 5C-4 and 5C-5 are cross-sectional representations of various stages of forming a semiconductor device structure, in accordance with some embodiments of the disclosure.

FIGS. 6A-1, 6A-2, 6A-3, 6B-1, 6B-2, 6B-3, 6B-4, 6B-5, 6C-1, 6C-2, 6C-3, 6C-4, 6C-5, 6D-1, 6D-2, 6D-3, 6D-4, 6D-5, 6E-1, 6E-2, 6E-3, 6E-4, 6E-5, 6F-1, 6F-2, 6F-3, 6F-4, 6F-5, 6G-1, 6G-2, 6G-3, 6G-4, 6G-5, 6H-1, 6H-2, 6H-3, 6H-4 and 6H-5 are cross-sectional representations of various stages of forming a semiconductor device structure, in accordance with some embodiments of the disclosure.

FIGS. 7A-1, 7A-2, 7A-3, 7B-1, 7B-2, 7B-3, 7C-1, 7C-2, 7C-3, 7C-4, 7C-5, 7D-1, 7D-2, 7D-3, 7D-4 and 7D-5 are cross-sectional representations of various stages of forming a semiconductor device structure, in accordance with some embodiments of the disclosure.

FIGS. 8A-1, 8A-2, 8A-3, 8A-4 and 8A-5 are cross-sectional representations of forming a semiconductor device structure, in accordance with some embodiments of the disclosure.

FIGS. 9A-1, 9A-2, 9A-3, 9A-4, 9A-5, 9B-1, 9B-2, 9B-3, 9B-4, 9B-5, 9C-1, 9C-2, 9C-3, 9C-4, 9C-5, 9D-1, 9D-2, 9D-3, 9D-4 and 9D-5 are cross-sectional representations of various stages of forming a semiconductor device structure, in accordance with some embodiments of the disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numbers are used to designate like elements. It should be understood that additional operations can be provided before, during, and after the method, and some of the operations described can be replaced or eliminated for other embodiments of the method.

The nanostructure transistor (e.g. nanosheet transistor, nanowire transistor, multi-bridge channel, nano-ribbon FET, gate all around (GAA) transistor structures) described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments for forming a semiconductor device structure are provided. The method for forming the semiconductor device structure may include recessing the isolation material surrounding the fin structure after removing the dummy gate structure. The capacitance may be reduced. In addition, the distance between the source/drain epitaxial structures may be increased, and adjacent source/drain epitaxial structures may not merge. The gate length in the isolation material may be smaller than the gate length wrapped around the nanostructures, and the capacitance may be further reduced. In addition, the dummy gate structure may not collapse, due to the lower aspect ratio during etching.

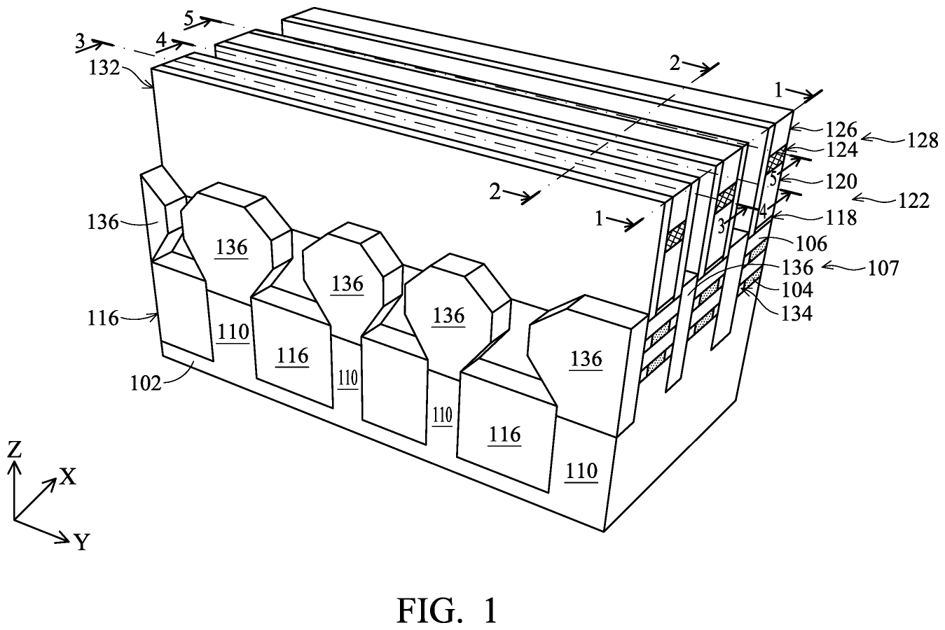

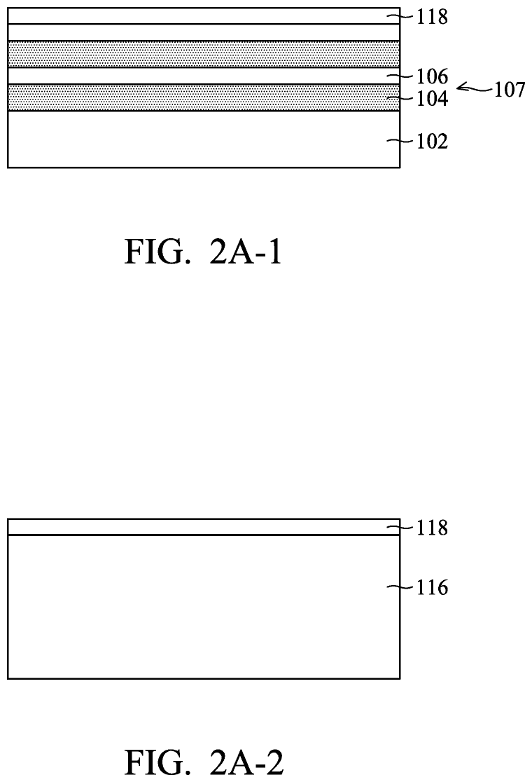

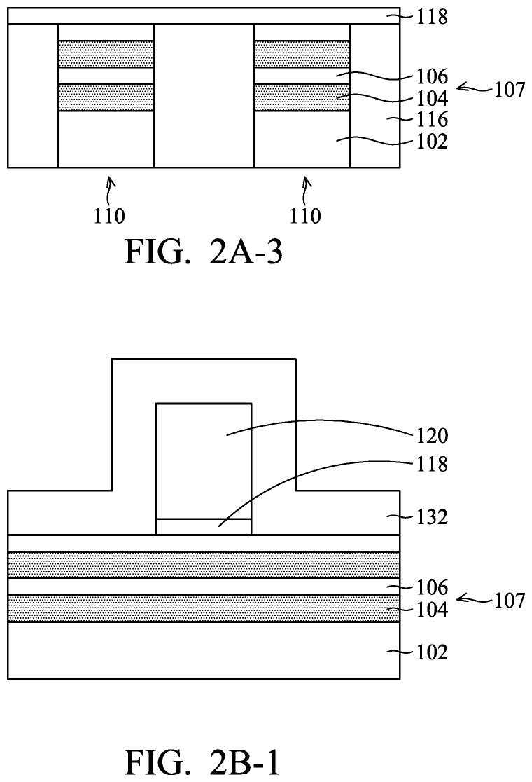

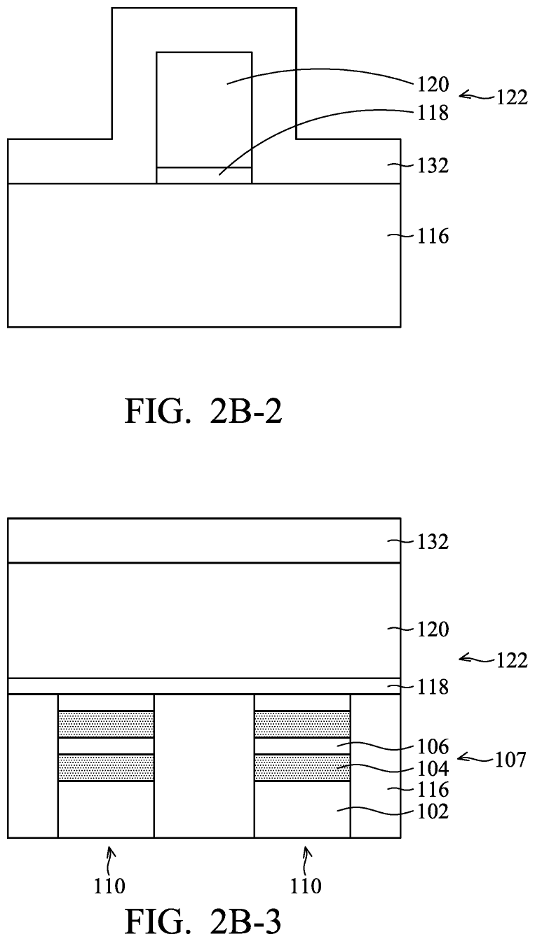

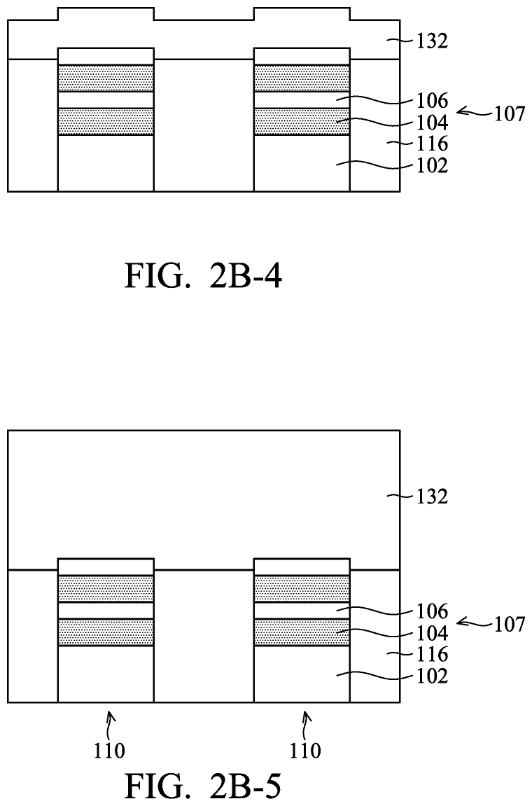

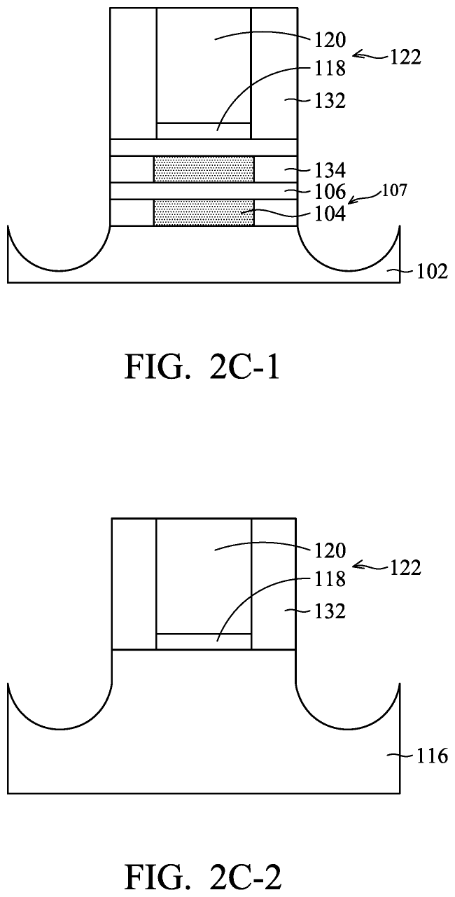

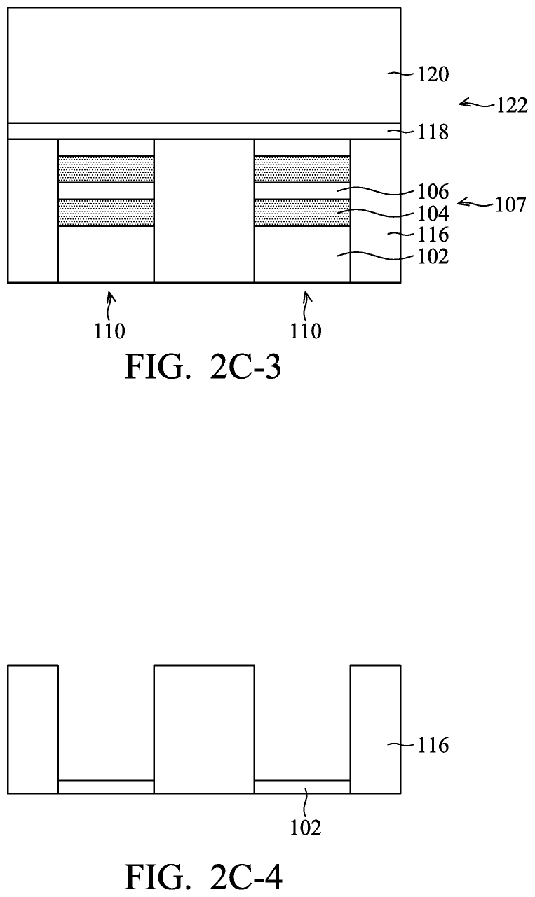

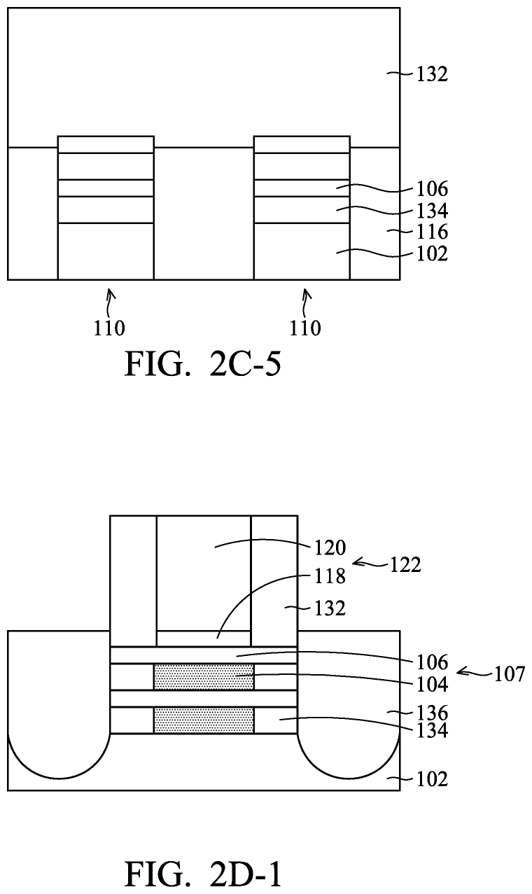

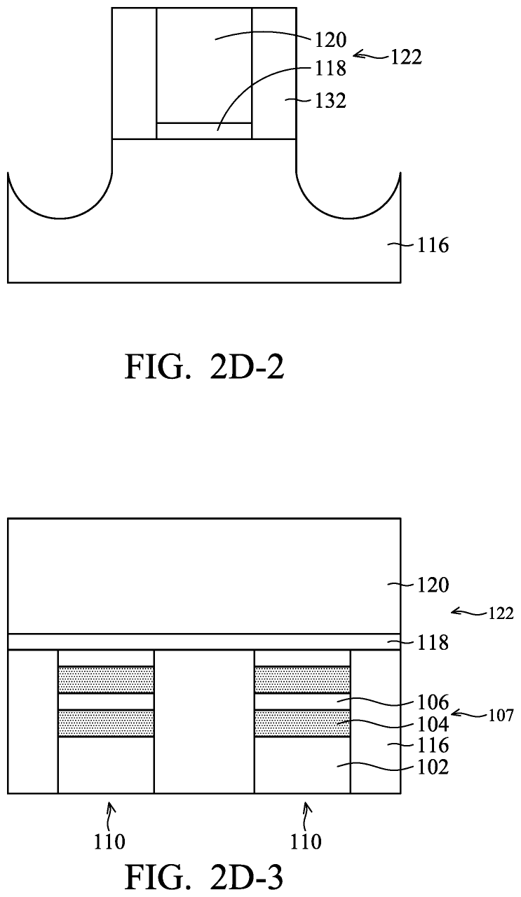

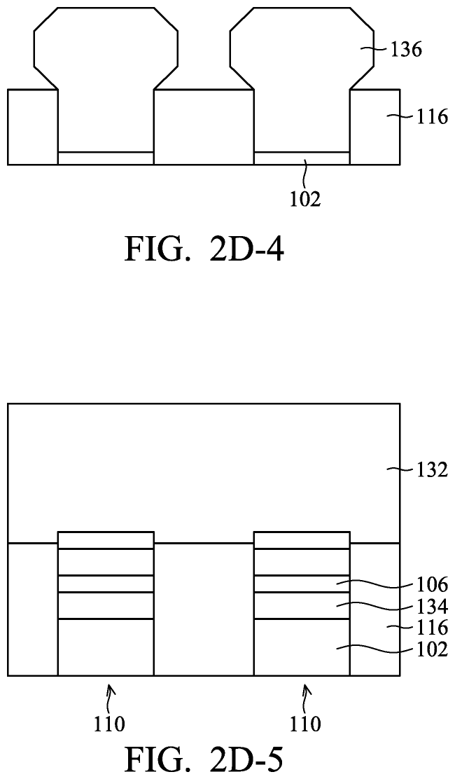

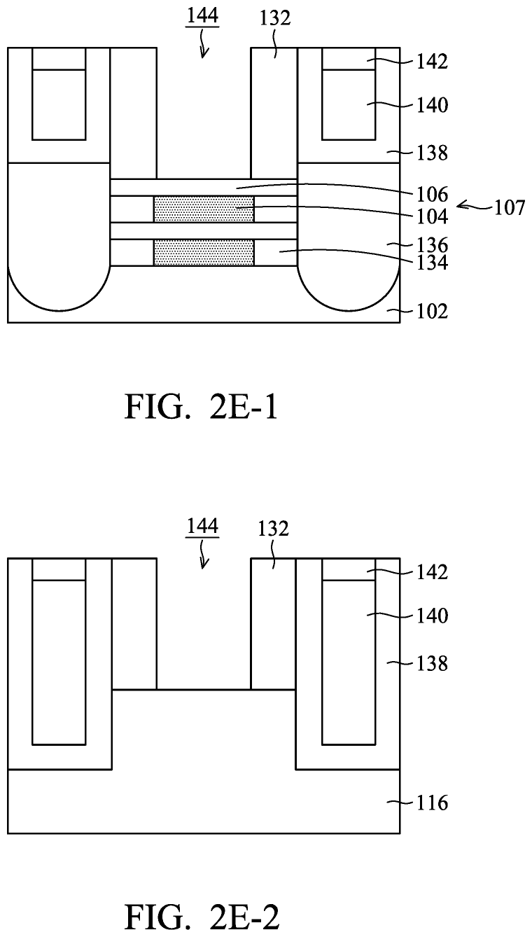

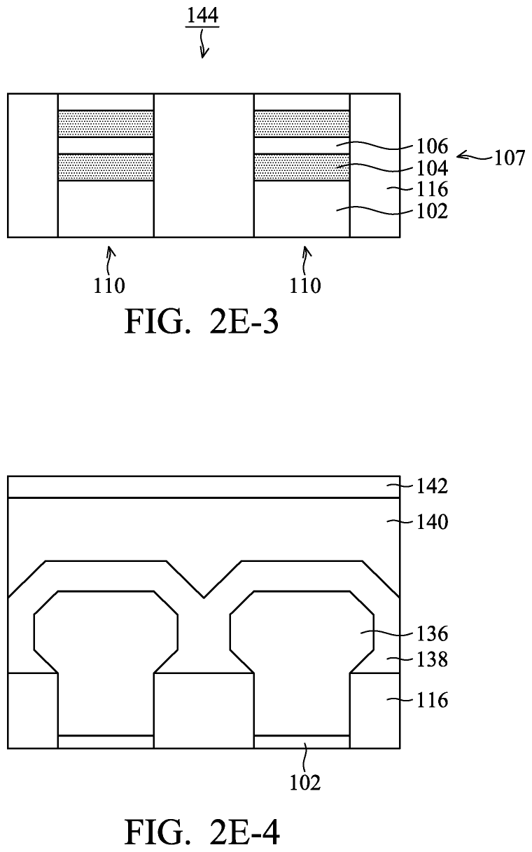

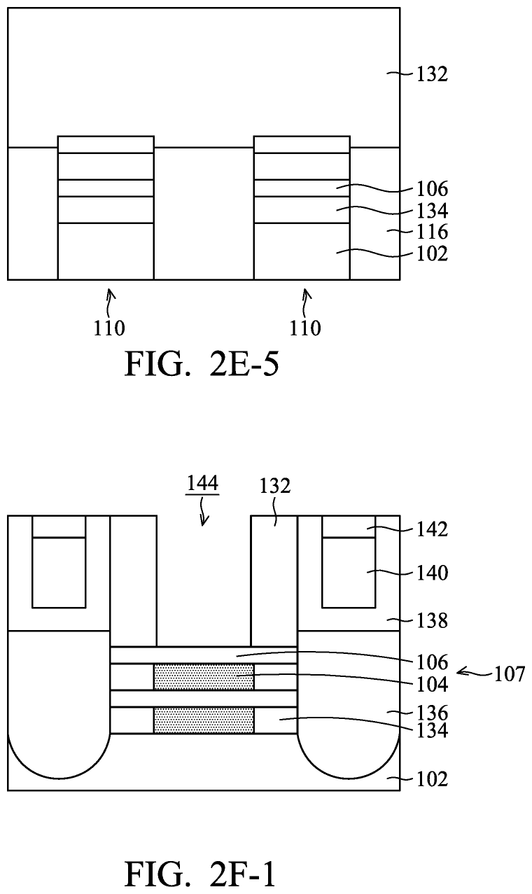

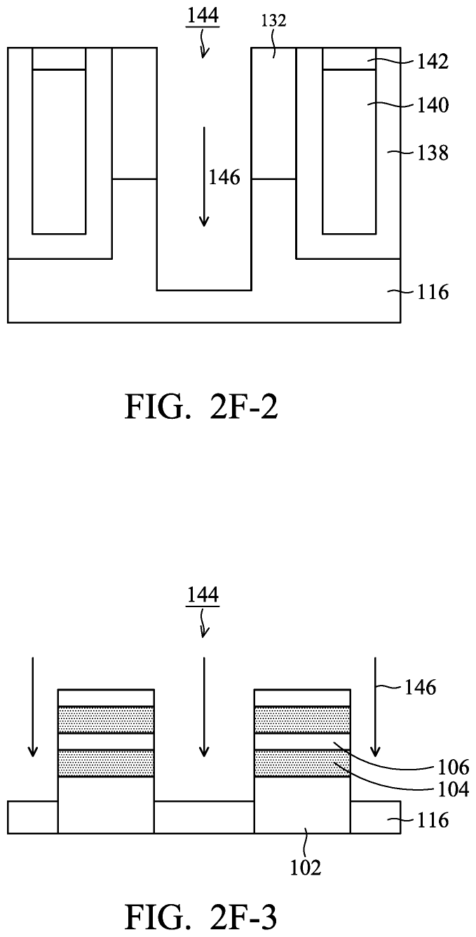

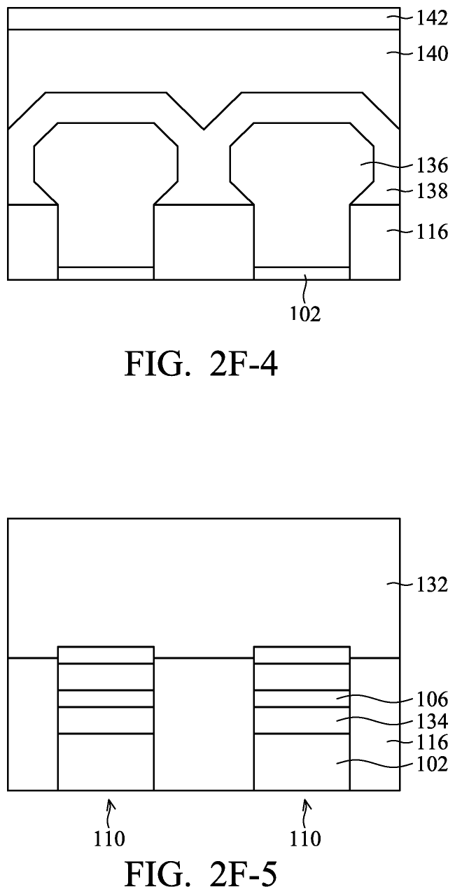

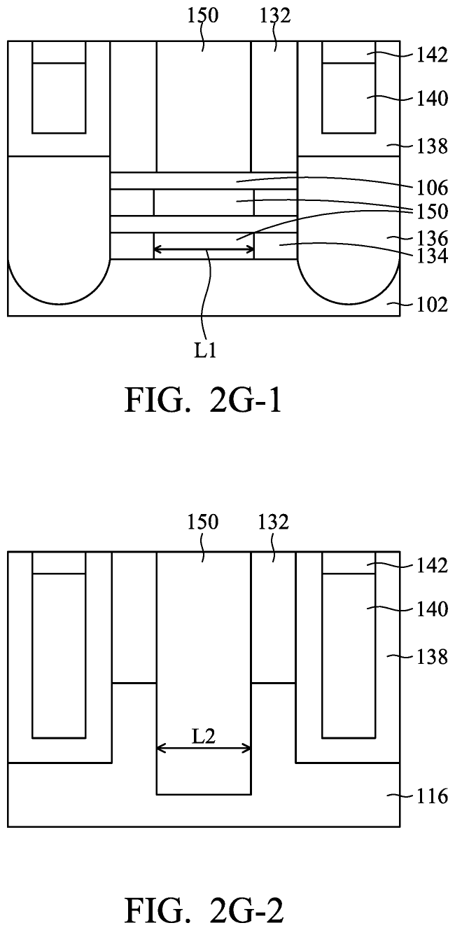

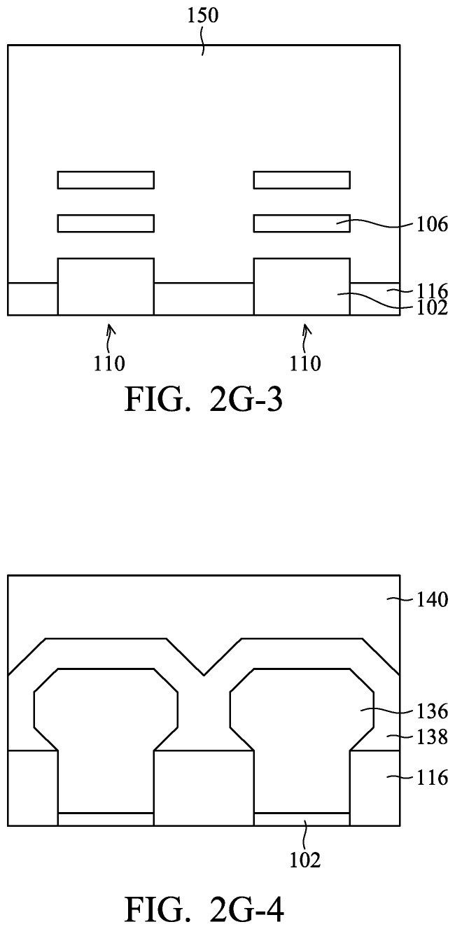

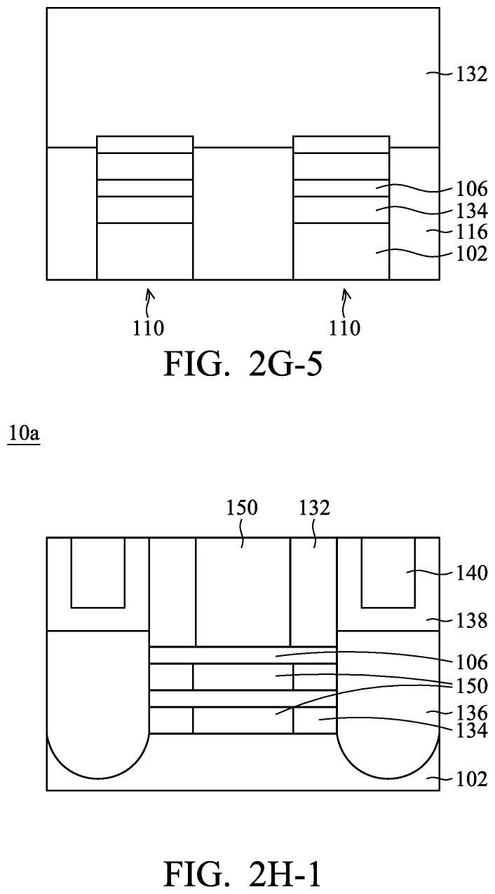

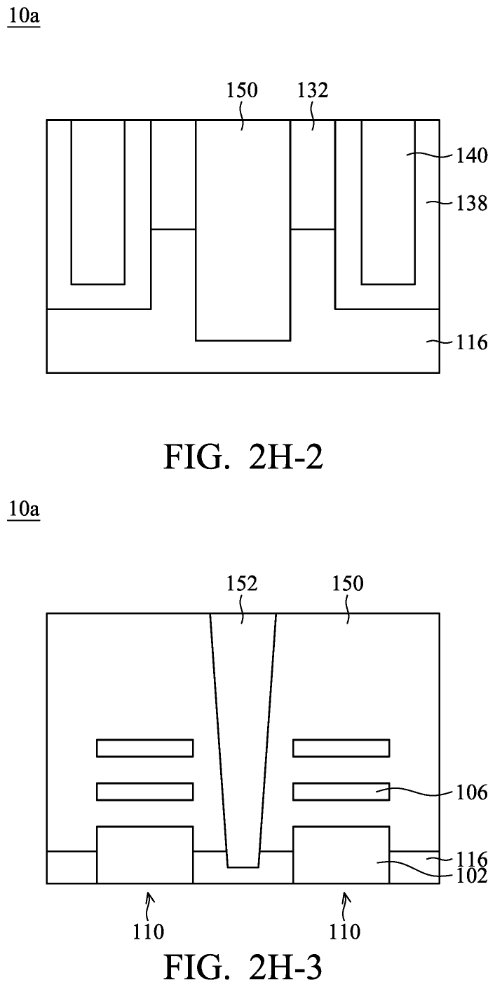

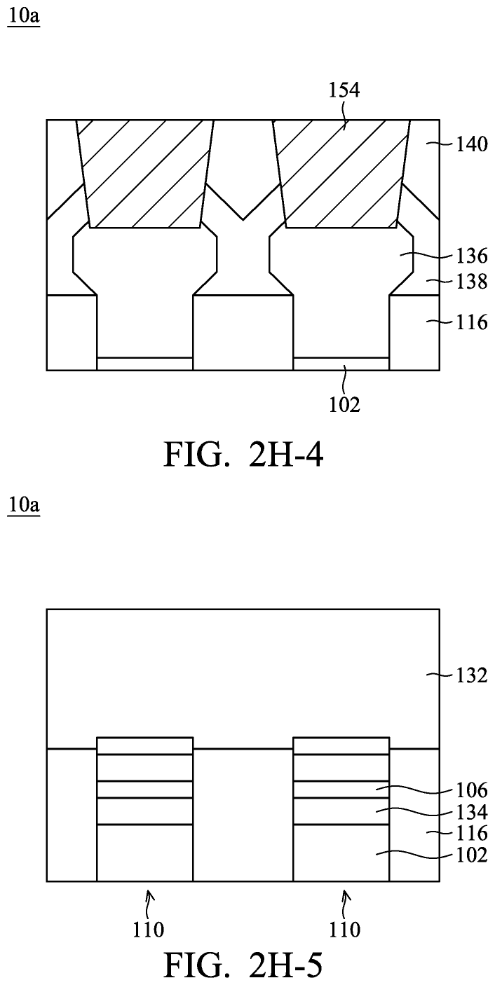

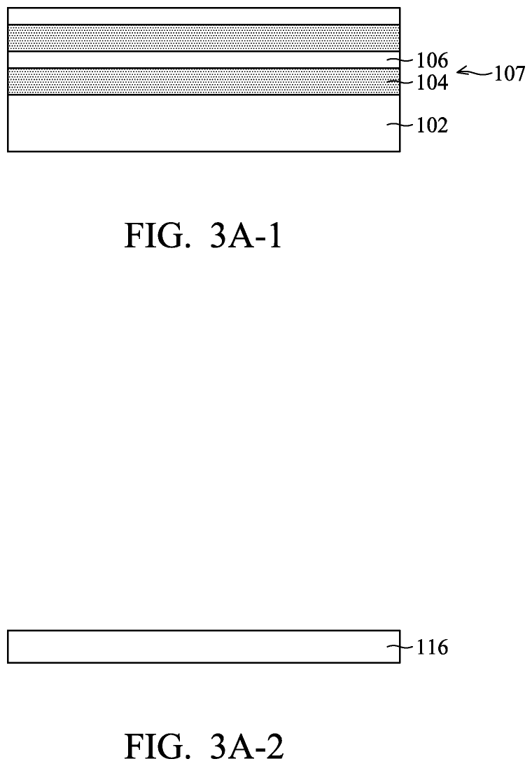

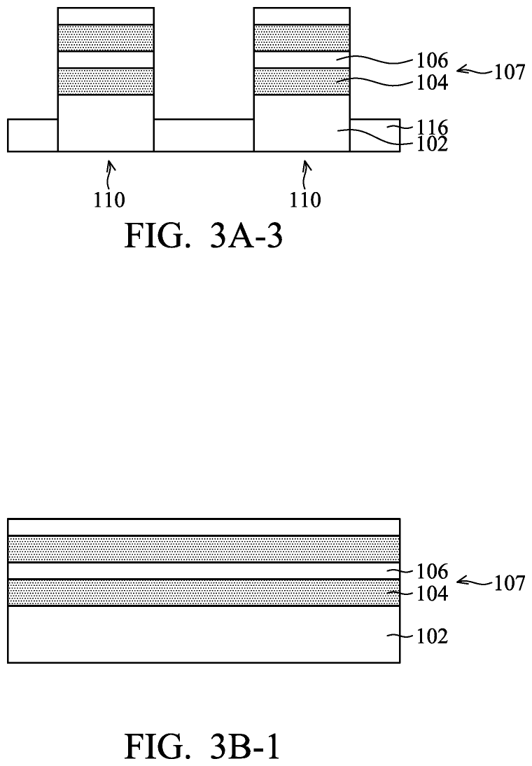

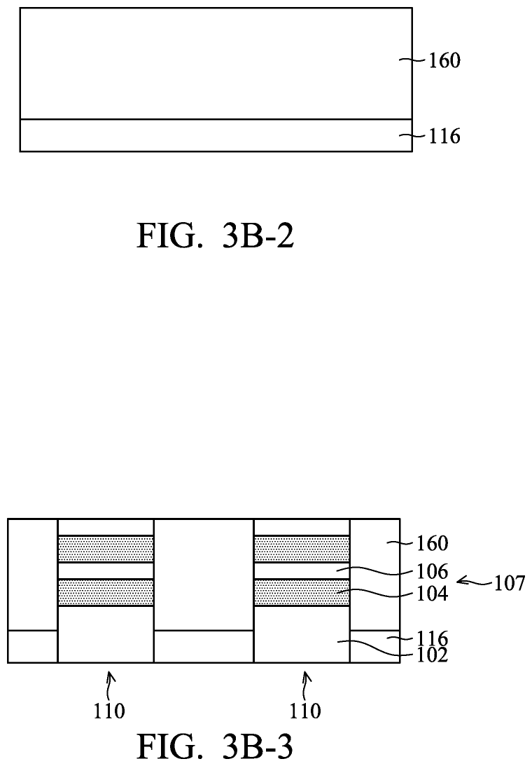

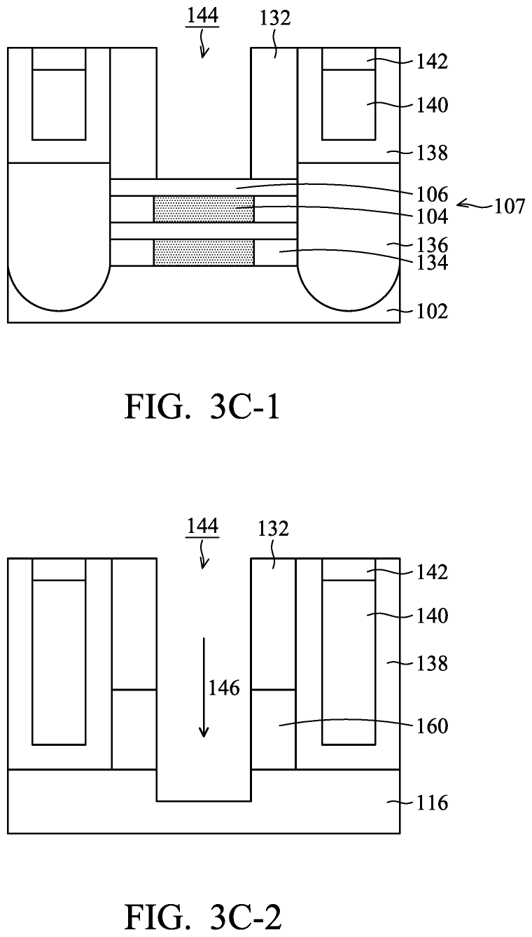

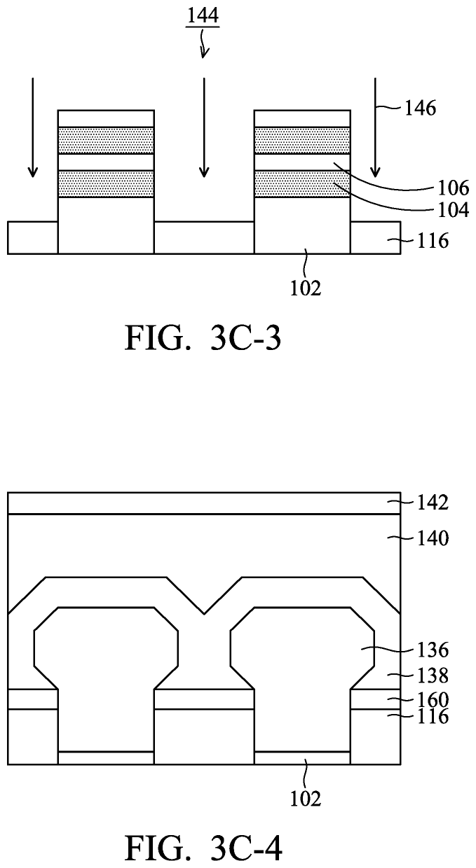

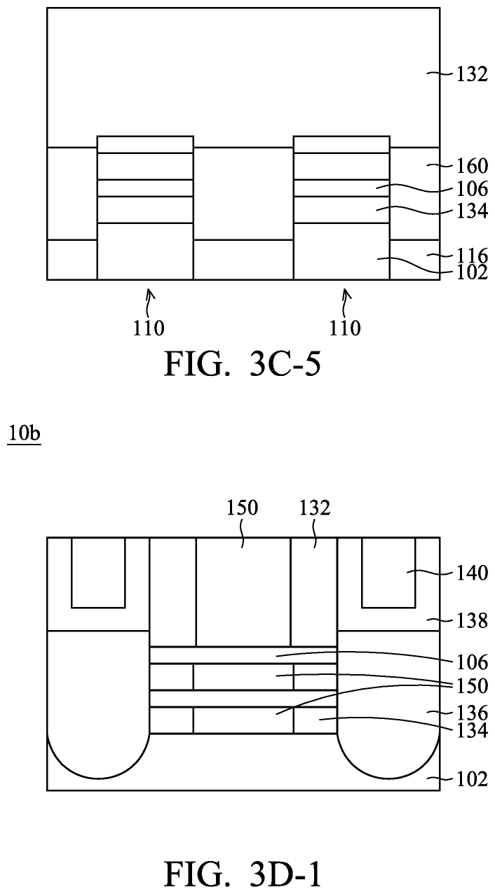

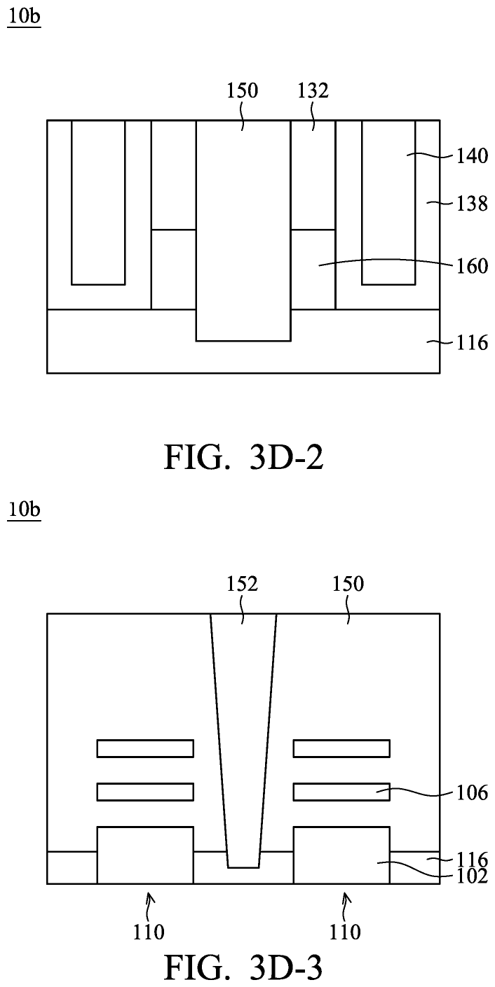

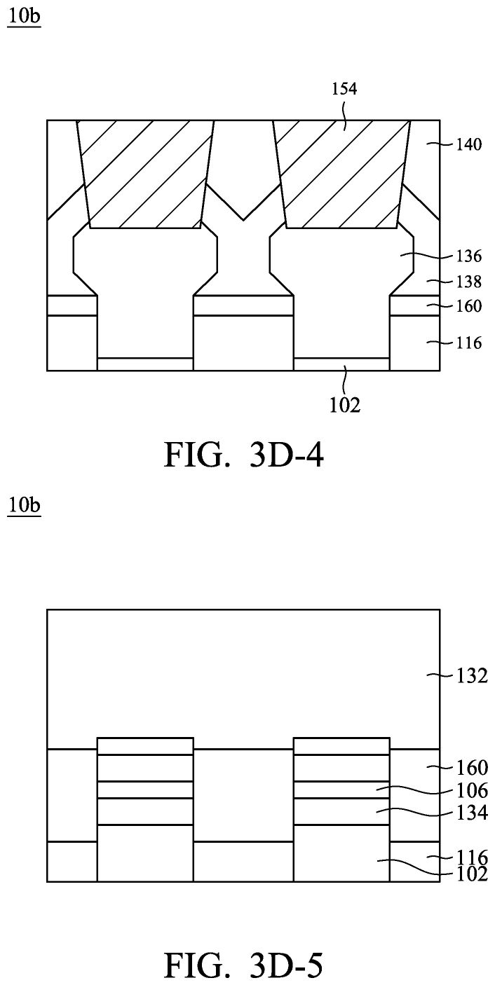

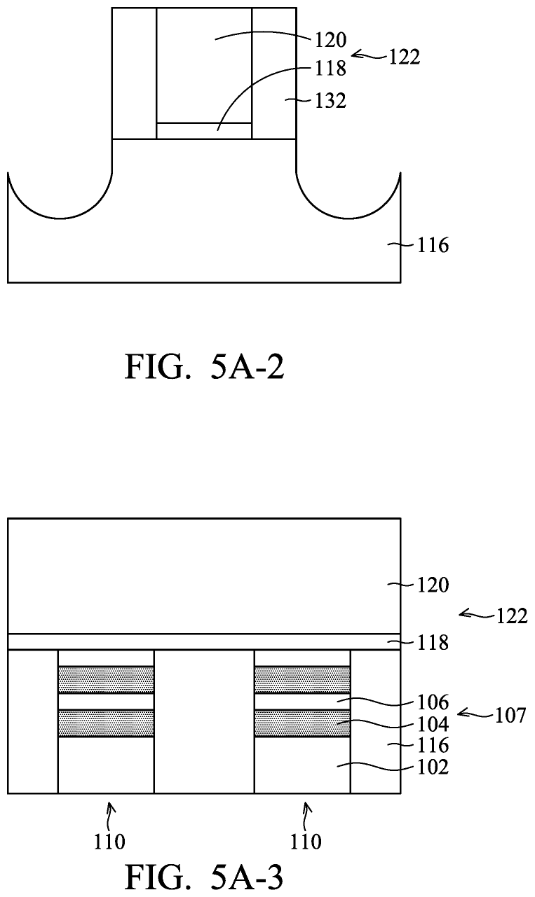

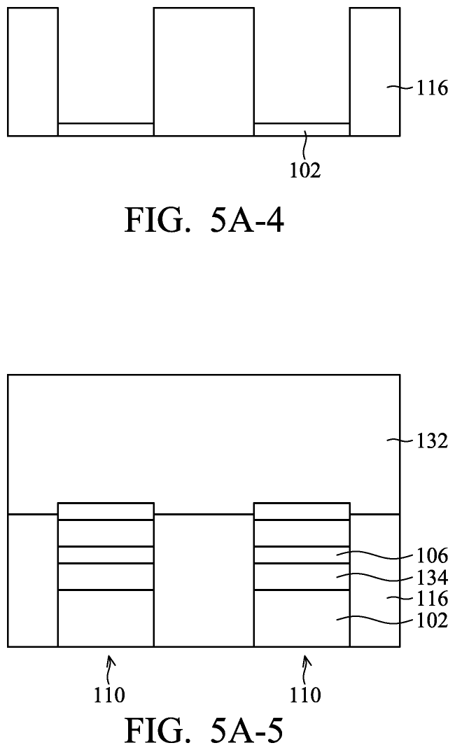

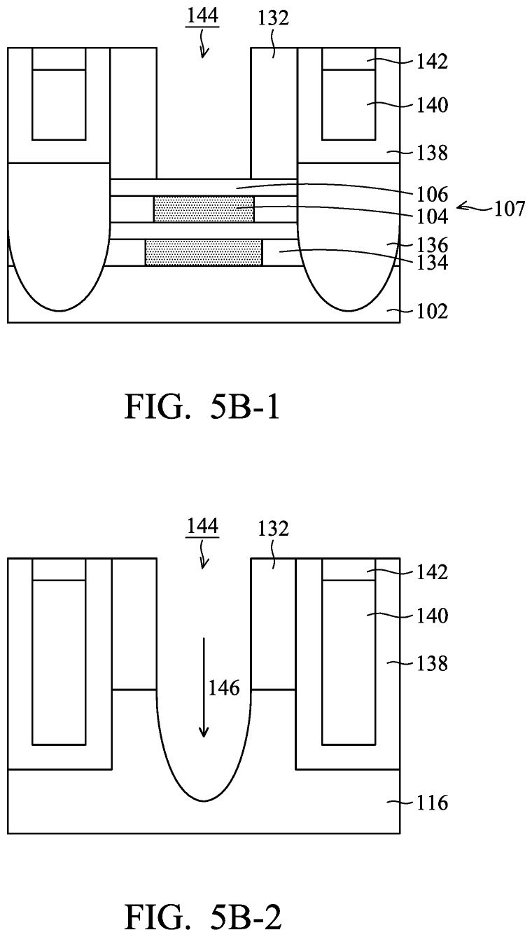

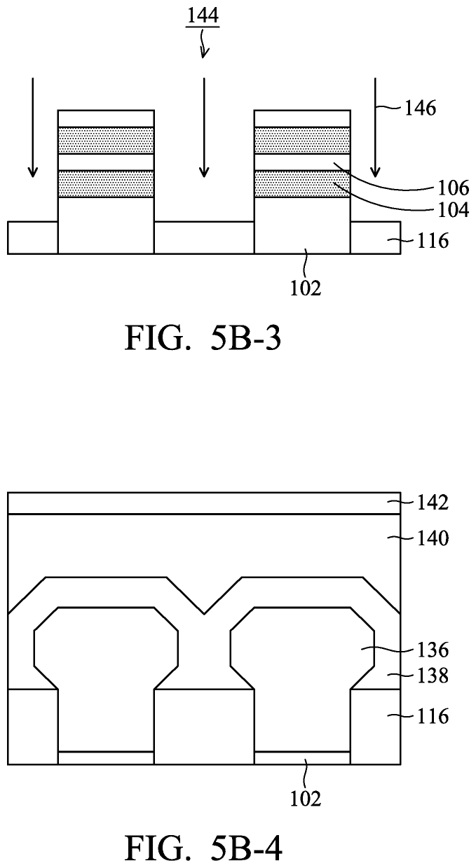

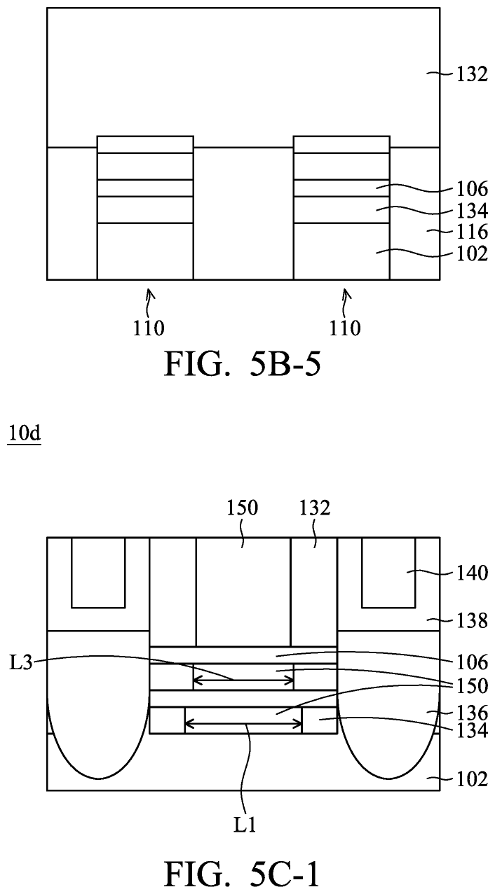

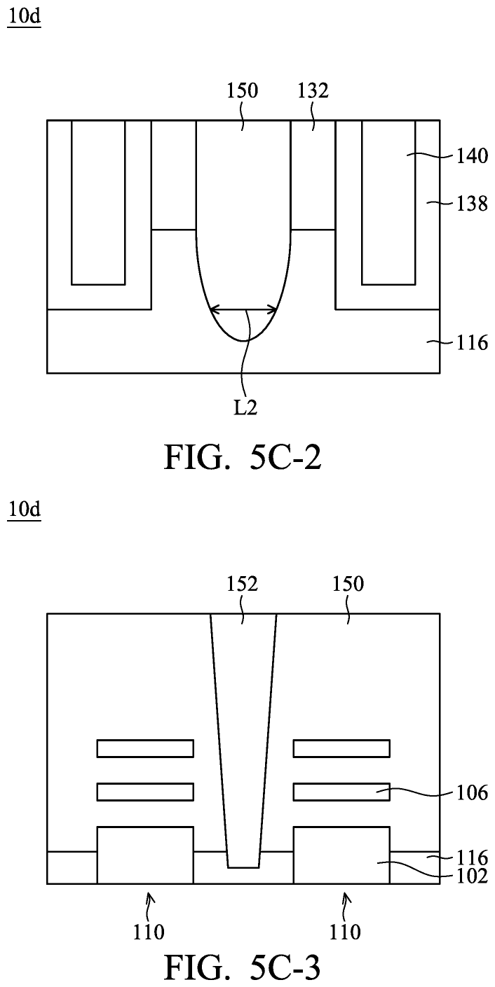

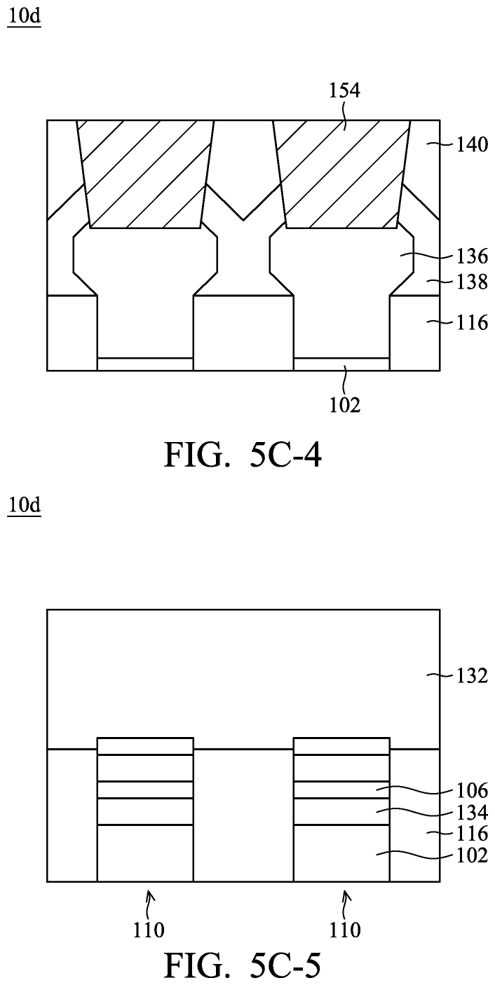

FIG. 1 is a perspective representation of a semiconductor device structure 10a, in accordance with some embodiments of the disclosure. The semiconductor device structure 10a may be a nanostructure transistor. FIGS. 2A-1, 2A-2, 2A-3, 2B-1, 2B-2, 2B-3, 2B-4, 2B-5, 2C-1, 2C-2, 2C-3, 2C-4, 2C-5, 2D-1, 2D-2, 2D-3, 2D-4, 2D-5, 2E-1, 2E-2, 2E-3, 2E-4, 2E-5, 2F-1, 2F-2, 2F-3, 2F-4, 2F-5, 2G-1, 2G-2, 2G-3, 2G-4, 2G-5, 2H-1, 2H-2, 2H-3, 2H-4, 2H-5 are cross-sectional representations of various stages of forming a semiconductor device structure 10a, in accordance with some embodiments of the disclosure. FIGS. 2A-1, 2B-1, 2C-1, 2D-1, 2E-1, 2F-1, 2G-1, 2H-1 show cross-sectional representations taken along line 1-1 in FIG. 1. FIGS. 2A-2, 2B-2, 2C-2, 2D-2, 2E-2, 2F-2, 2G-2, 2H-2 show cross-sectional representations taken along line 2-2 in FIG. 1. FIGS. 2A-3, 2B-3, 2C-3, 2D-3, 2E-3, 2F-3, 2G-3, 2H-3 show cross-sectional representations taken along line 3-3 in FIG. 1. FIGS. 2B-4, 2C-4, 2D-4, 2E-4, 2F-4, 2G-4, 2H-4 show cross-sectional representations taken along line 4-4 in FIG. 1. FIGS. 2B-5, 2C-5, 2D-5, 2E-5, 2F-5, 2G-5, 2H-5 show cross-sectional representations taken along line 5-5 in FIG. 1.

A semiconductor stack including first semiconductor material layers 104 and second semiconductor material layers 106 are formed over a substrate 102, as shown in FIGS. 1, 2A-1, 2A-2, 2A-3, 2A-4 and 2A-5 in accordance with some embodiments. The substrate 102 may be a semiconductor wafer such as a silicon wafer. The substrate 102 may also include other elementary semiconductor materials, compound semiconductor materials, and/or alloy semiconductor materials. Examples of the elementary semiconductor materials may include, but are not limited to, crystal silicon, polycrystalline silicon, amorphous silicon, germanium, and/or diamond. Examples of the compound semiconductor materials may include, but are not limited to, silicon carbide, gallium nitride, gallium arsenic, gallium phosphide, indium phosphide, indium arsenide, and/or indium antimonide. Examples of the alloy semiconductor materials may include, but are not limited to, SiGe, GaAsP, AlInAs, AlGaAs, GaInAs, GaInP, and/or GaInAsP. The substrate 102 may include an epitaxial layer. For example, the substrate 102 may be an epitaxial layer overlying a bulk semiconductor. In addition, the substrate 102 may also be semiconductor on insulator (SOI). The SOI substrate may be fabricated by a wafer bonding process, a silicon film transfer process, a separation by implantation of oxygen (SIMOX) process, other applicable methods, or a combination thereof. The substrate 102 may be an N-type substrate. The substrate 102 may be a P-type substrate.

Next, first semiconductor material layers 104 and second semiconductor material layers 106 are alternating stacked over the substrate 102 to form the semiconductor stack 107, as shown in FIGS. 1, 2A-1, 2A-2 and 2A-3 in accordance with some embodiments. The first semiconductor material layers 104 and the second semiconductor material layers 106 may include Si, Ge, SiGe, GaAs, InSb, GaP, GaSb, InAlAs, InGaAs, GaSbP, GaAsSb, or InP. The first semiconductor material layers 104 and second semiconductor material layers 106 may be made of different materials with different etching rates. In some embodiments, the first semiconductor material layers 104 are made of SiGe and the second semiconductor material layers 106 are made of Si.

The first semiconductor material layers 104 and second semiconductor material layers 106 may be formed by low pressure chemical vapor deposition (LPCVD) process, epitaxial growth process, other applicable methods, or a combination thereof. The epitaxial growth process may include molecular beam epitaxy (MBE), metal organic chemical vapor deposition (MOCVD), or vapor phase epitaxy (VPE).

It should be noted that, although there are two layers of the first semiconductor material layers 104 and two layers of the second semiconductor material layers 106 shown in FIGS. 1, 2A-1, 2A-2 and 2A-3, the number of the first semiconductor material layers 104 and second semiconductor material layers 106 are not limited herein, depending on the demand of performance and process. For example, the semiconductor structure may include two to five layers of the first semiconductor material layers 104 and two to five layers of the second semiconductor material layers 106.

Next, a mask structure is formed over the semiconductor stack 107. The mask structure may be made of silicon nitride, silicon carbon nitride (SiCN), or applicable material. The mask structure may be formed by a deposition process, such as low-pressure CVD (LPCVD) process, plasma enhanced CVD (PECVD) process, or another deposition process.

After the first semiconductor material layers 104 and the second semiconductor material layers 106 are formed as the semiconductor stack 107 over the substrate 102, the semiconductor stack 107 is patterned to form fin structures 110 using the mask structure as a mask layer, as shown in FIGS. 1, 2A-1, 2A-2 and 2A-3 in accordance with some embodiments. The fin structures 110 may include base fin structures and the semiconductor stacks 107, including the first semiconductor material layers 104 and the second semiconductor material layers 106, formed over the base fin structure.

The patterning process may include forming a mask structure over the first semiconductor material layers 104 and the second semiconductor material layers 106 and etching the semiconductor stack 107 and the underlying substrate 102 through the mask structure. The mask structure may be a multilayer structure including a pad layer and a hard mask layer formed over the pad layer. The pad layer may be made of silicon oxide, which may be formed by thermal oxidation or CVD. The hard mask layer may be made of silicon nitride, which may be formed by CVD, such as LPCVD or plasma-enhanced CVD (PECVD).

The patterning process of forming the fin structures 110 may include a photolithography process and an etching process. The photolithography process may include photoresist coating (e.g., spin-on coating), soft baking, mask aligning, exposure, post-exposure baking, developing the photoresist, rinsing and drying (e.g., hard baking). The etching process may include a dry etching process or a wet etching process.

After the fin structures 110 are formed, a liner layer is formed over the fin structures 110 and in the trenches between the fin structures 110. The liner layer may be conformally formed over the substrate 102, the fin structure 110, and the mask structure covering the fin structure 110. The liner layer may be used to protect the fin structure 110 from being damaged in the following processes (such as an anneal process or an etching process). The liner layer may be made of silicon nitride. The liner layer may be formed by using a thermal oxidation, a CVD process, an atomic layer deposition (ALD) process, a LPCVD process, a plasma enhanced CVD (PECVD) process, a HDPCVD process, a flowable CVD (FCVD) process, another applicable process, or a combination thereof.

Next, an isolation structure material 116 is then filled into the trenches between the fin structures 110 and over the liner layer, as shown in FIGS. 1, 2A-1, 2A-2 and 2A-3 in accordance with some embodiments. The isolation structure material 116 may be made of silicon oxide, silicon nitride, silicon oxynitride (SiON), fluoride-doped silicate glass (FSG), SiCN, SiCON, SiCO, high-k dielectric materials such as HfO, AlO, other dielectric materials, or a combination thereof. The isolation structure material 116 may be deposited by a deposition process, such as a chemical vapor deposition (CVD) process (e.g. a flowable CVD (FCVD) process), a spin-on-glass process, or another applicable process. In some embodiments, the top surface of the isolation structure material 116 is substantially level with the top surface of the semiconductor stack 107.

Next, a dummy gate structure 122 is formed over and across the fin structures 110, as shown in FIGS. 1, 2B-1, 2B-2, 2B-3, 2B-4 and 2B-5 in accordance with some embodiments. The dummy gate structure 122 may be used to define the source/drain regions and the channel regions of the resulting semiconductor structure 10a. The dummy gate structure 122 may include a dummy gate dielectric layer 118 and a dummy gate electrode layer 120. The dummy gate dielectric layer 118 and the dummy gate electrode layer 120 may be replaced by the following steps to form a real gate structure with a high-k dielectric layer and a metal gate electrode layer.

The dummy gate dielectric layer 118 may include one or more dielectric materials, such as silicon oxide, silicon nitride, silicon oxynitride (SiON), HfO₂, HfZrO, HfSiO, HfTiO, HfAlO, or a combination thereof. The dummy gate dielectric layer 118 may be formed by an oxidation process (e.g., a dry oxidation process, or a wet oxidation process), a chemical vapor deposition process, other applicable processes, or a combination thereof. Alternatively, the dummy gate dielectric layer 118 may include a high-k dielectric layer (e.g., the dielectric constant is greater than 3.9) such as hafnium oxide (HfO₂). Alternatively, the high-k dielectric layer may include other high-k dielectrics, such as LaO, AlO, ZrO, TiO, Ta₂O₅, Y₂O₃, SrTiO₃, BaTiO₃, BaZrO, HfZrO, HfLaO, HfTaO, HfSiO, HfSiON, HfTiO, LaSiO, AlSiO, (Ba, Sr)TiO₃, Al₂O₃, other applicable high-k dielectric materials, or a combination thereof. The high-k dielectric layer may be formed by a chemical vapor deposition process (e.g., a plasma enhanced chemical vapor deposition (PECVD) process, or a metalorganic chemical vapor deposition (MOCVD) process), an atomic layer deposition (ALD) process (e.g., a plasma enhanced atomic layer deposition (PEALD) process), a physical vapor deposition (PVD) process (e.g., a vacuum evaporation process, or a sputtering process), other applicable processes, or a combination thereof.

The dummy gate electrode layer 120 may include polycrystalline-silicon (poly-Si), poly-crystalline silicon-germanium (poly-SiGe), other applicable materials, or a combination thereof. The dummy gate electrode layer 120 may be formed by a chemical vapor deposition process (e.g., a low pressure chemical vapor deposition process, or a plasma enhanced chemical vapor deposition process), a physical vapor deposition process (e.g., a vacuum evaporation process, or a sputtering process), other applicable processes, or a combination thereof.

Hard mask layers 128 are formed over the dummy gate structure 122, as shown in FIG. 1 in accordance with some embodiments. The hard mask layers 128 may include multiple layers, such as an oxide layer 124 and a nitride layer 126. In some embodiments, the oxide layer 124 includes silicon oxide, and the nitride layer 126 includes silicon nitride.

The formation of the dummy gate structure 122 may include conformally forming a dielectric material as the dummy gate dielectric layer 118. Afterwards, a conductive material may be formed over the dielectric material as the dummy gate electrode layers 120, and the bi-layered hard mask layers 128, including the oxide layer 124 and the nitride layer 126, may be formed over the conductive material. Next, the dielectric material and the conductive material may be patterned and etched through the bi-layered hard mask layers 128 to form the dummy gate structure 122, as shown in FIGS. 1, 2B-1, 2B-2, 2B-3, 2B-4 and 2B-5 in accordance with some embodiments. The dummy gate dielectric layer 118 and the dummy gate electrode layer 120 may be etched by a dry etching process. After the etching process, the first semiconductor material layers 104 and the second semiconductor material layers 106 may be exposed on opposite sides of the dummy gate structure 122.

Next, a spacer layer material 132 is formed over the substrate 102 and the dummy gate structure 122, as shown in FIGS. 2B-1, 2B-2, 2B-3, 2B-4 and 2B-5 in accordance with some embodiments. The spacer layer material 132 may include different materials with different etching selectivity. The spacer layer material 132 may be made of silicon oxide, silicon nitride, silicon oxynitride, and/or dielectric materials. The spacer layer material 132 may be formed by a chemical vapor deposition (CVD) process, a spin-on-glass process, or another applicable process. In some embodiments, the dielectric constant of the spacer layer material 132 is in a range of about 3.9 to about 7.

Later, an etching process is performed. A pair of spacer layers 132 is formed over opposite sidewalls of the dummy gate structure 122, and a source/drain opening is formed beside the dummy gate structure 122, as shown in FIGS. 2C-1, 2C-2, 2C-3, 2C-4 and 2C-5 in accordance with some embodiments.

After the spacer layers 132 are formed, the first semiconductor material layers 104 and the second semiconductor material layers 106 of the fin structure 110 not covered by the dummy gate structure 122 and the spacer layers 132 are etched to form the trenches beside the dummy gate structure 122, as shown in FIGS. 2C-1, 2C-2, 2C-3, 2C-4 and 2C-5 in accordance with some embodiments.

The fin structures 110 may be recessed by performing a number of etching processes. That is, the first semiconductor material layers 104 and the second semiconductor material layers 106 of the fin structures 110 may be etched in different etching processes. The etching process may be a dry etching process or a wet etching process. The fin structures 110 may be etched by a dry etching process.

In some embodiments, the spacer layers 132 formed over the isolation structure material 116 is removed, and the top surface of the isolation structure material 116 is exposed in a cross-sectional view outside the dummy gate structure 122 along the extending direction of the dummy gate structure 122.

In some embodiments, after the etching process, the isolation material 116 between the source/drain openings has a flat top surface. In addition, the bottom surface of the source/drain openings is higher than the bottom surface of the first semiconductor layer 104 of the semiconductor stack 107.

Next, the first semiconductor material layers 104 may be laterally etched from the source/drain opening to form recesses. The outer portions of the first semiconductor material layers 104 may be removed, and the inner portions of the first semiconductor material layers 104 under the dummy gate structure 122 and the spacer layers 132 may remain. After the lateral etching process, the sidewalls of the etched first semiconductor material layers 104 may be not aligned with the sidewalls of the second semiconductor material layers 106.

The lateral etching of the first semiconductor material layers 104 may be a dry etching process, a wet etching process, or a combination thereof. In some embodiments, the first semiconductor material layers 104 are Ge or SiGe and the second semiconductor material layers 106 are Si, and the first semiconductor material layers 104 are selectively etched to form the recesses by using a wet etchant such as, but not limited to, ammonium hydroxide (NH₄OH), tetramethylammonium hydroxide (TMAH), ethylenediamine pyrocatechol (EDP), or potassium hydroxide (KOH) solutions, or the like.

Next, an inner spacer 134 is formed in the recess, as shown in FIGS. 2C-1, 2C-2, 2C-3, 2C-4 and 2C-5 in accordance with some embodiments. The inner spacer 134 may provide a barrier between subsequently formed source/drain epitaxial structures and gate structure. The inner spacer 134 may be made of dielectric material such as silicon oxide (SiO₂), silicon nitride (SiN), silicon carbide (SiC), silicon oxynitride (SiON), silicon carbon nitride (SiCN), silicon oxide carbonitride (SiOCN), or a combination thereof. The inner spacer 134 may be formed using a deposition process. The deposition process may include a CVD process (such as LPCVD, PECVD, SACVD, or FCVD), an ALD process, another applicable method, or a combination thereof. In some embodiments, the dielectric constant of the inner spacer 134 is in a range of about 3.9 to about 7.

In some embodiments, the dielectric constant of the isolation structure material 116 is lower than the dielectric constants of the spacer layer 132 and the inner spacer 134.

Next, a source/drain epitaxial structure 136 is formed in the source/drain opening, as shown in FIGS. 2D-1, 2D-2, 2D-3, 2D-4 and 2D-5 in accordance with some embodiments. The source/drain epitaxial structure 136 may be formed over opposite sides of the dummy gate structure 122. Source/drain epitaxial structure 136 may refer to a source or a drain, individually or collectively dependent upon the context.

A strained material may be grown in the source/drain opening using an epitaxial (epi) process to form the source/drain epitaxial structure 136. In addition, the lattice constant of the strained material may be different from the lattice constant of the substrate 102. The source/drain epitaxial structure 136 may include SiGeB, SiP, SiAs, SiGe, other applicable materials, or a combination thereof. The source/drain epitaxial structure 136 may be formed by an epitaxial growth step, such as metalorganic chemical vapor deposition (MOCVD), metalorganic vapor phase epitaxy (MOVPE), plasma-enhanced chemical vapor deposition (PECVD), remote plasma-enhanced chemical vapor deposition (RP-CVD), molecular beam epitaxy (MBE), hydride vapor phase epitaxy (HVPE), liquid phase epitaxy (LPE), chloride vapor phase epitaxy (Cl-VPE), or any other suitable method.

The source/drain epitaxial structure 136 may be in-situ doped during the epitaxial growth process. For example, the source/drain epitaxial structures 136 may be the epitaxially grown SiGe doped with boron (B). For example, the source/drain epitaxial structure 136 may be the epitaxially grown Si doped with carbon to form silicon:carbon (Si:C) source/drain features, phosphorous to form silicon:phosphor (Si:P) source/drain features, or both carbon and phosphorous to form silicon carbon phosphor (SiCP) source/drain features. The source/drain epitaxial structure 136 may be doped in one or more implantation processes after the epitaxial growth process.

Next, a contact etch stop layer 138 is formed over the source/drain epitaxial structure 136, as shown in FIGS. 2E-1, 2E-2, 2E-3, 2E-4 and 2E-5 in accordance with some embodiments. More specifically, the contact etch stop layer 138 covers the sidewalls of the spacer layers 132 and the source/drain epitaxial structures 136 in accordance with some embodiments.

The contact etch stop layer 138 may be made of a dielectric material such as silicon nitride, silicon oxide, silicon oxynitride (SiON), other applicable materials, or a combination thereof. The contact etch stop layer 138 may be formed by a chemical vapor deposition process (e.g., a plasma enhanced chemical vapor deposition (PECVD) process, or a metalorganic chemical vapor deposition (MOCVD) process), an atomic layer deposition (ALD) process (e.g., a plasma enhanced atomic layer deposition (PEALD) process), a physical vapor deposition (PVD) process (e.g., a vacuum evaporation process, or a sputtering process), other applicable processes, or a combination thereof.

After the contact etch stop layer 138 is formed, an inter-layer dielectric (ILD) structure 140 is formed over the contact etch stop layer 138, as shown in FIGS. 2E-1, 2E-2, 2E-3, 2E-4 and 2E-5 in accordance with some embodiments. The ILD structure 140 may include multilayers made of multiple dielectric materials, such as silicon oxide (SiOₓ, where x may be a positive integer), silicon oxycarbide (SiCO_{y}, where y may be a positive integer), silicon oxycarbonitride (SiNCO_{z}, where z may be a positive integer), silicon nitride, silicon oxynitride, phosphosilicate glass (PSG), borophosphosilicate glass (BPSG), low-k dielectric material, or another applicable dielectric material. Examples of low-k dielectric materials include, but are not limited to, fluorinated silica glass (FSG), carbon doped silicon oxide, amorphous fluorinated carbon, parylene, bis-benzocyclobutenes (BCB), or polyimide. The ILD structure 140 may be formed by chemical vapor deposition (CVD), physical vapor deposition (PVD), atomic layer deposition (ALD), spin-on coating, or another applicable process.

Afterwards, a planarizing process or an etch-back process may be performed on the ILD structure 140 until the top surface of the dummy gate structure 122 is exposed. After the planarizing process, the top surface of the dummy gate structure 122 may be substantially level with the top surfaces of the spacer layers 132 and the ILD structure 140. The planarizing process may include a grinding process, a chemical mechanical polishing (CMP) process, an etching process, other applicable processes, or a combination thereof.

Next, as shown in FIGS. 2E-1, 2E-2, 2E-3, 2E-4 and 2E-5, a protective layer 142 is formed over the ILD layer 140, and dummy gate structure 122 is removed to form a trench 144, in accordance with some embodiments. The trench 144 is formed between the spacer layers 132 over the fin structure 110 and the first semiconductor material layers 104 are exposed from the trench.

The protective layer 142 is used to protect the underlying ILD layer 140, preventing ILD layer 140 consume in the following etching processes. The protective layer 142 is formed by removing the top portion of the ILD layer 140 to form a recess, and the protective layer 142 is formed in the recess, and then the excess protective layer 142 outside of the recess is removed to form the protective layer 142 over the ILD layer 140.

The protective layer 142 may be made of a dielectric material, such as silicon nitride (SiN), silicon oxide (SiO₂), silicon carbide (SiC), silicon oxynitride (SiON), silicon carbon nitride (SiCN), silicon oxide carbonitride (SiOCN), or a combination thereof. The protective layer 142 may be formed by a deposition process, such as chemical vapor deposition (CVD), physical vapor deposition, (PVD), atomic layer deposition (ALD), or another applicable process.

The dummy gate structure 122 may be removed by a dry etching process or a wet etching process. The removal process may include one or more etching processes. For example, when the dummy gate electrode layer 120 is polysilicon, a wet etchant such as a tetramethylammonium hydroxide (TMAH) solution may be used to selectively remove the dummy gate electrode layer 120. Afterwards, the dummy gate dielectric layer 118 may be removed using a plasma dry etching, a dry chemical etching, and/or a wet etching.

Next, the isolation structure material 116 and the liner layer exposed by the trench 144 are etched back using an etching process 146, and an isolation structure 116 is formed surrounding the base fin structure, as shown in FIGS. 2F-1, 2F-2, 2F-3, 2F-4 and 2F-5 in accordance with some embodiments. The etching process may be used to remove the top portion of the liner layer and the top portion of the isolation structure material 116. In some embodiments, the etching process 146 is a dry etching process.

As a result, the first semiconductor material layers 104 and the second semiconductor material layers 106 may be exposed. The isolation structure 116 may be a shallow trench isolation (STI) structure 116. The isolation structure 116 may be configured to electrically isolate active regions such as fin structures 110 of the semiconductor structure 10a and prevent electrical interference and crosstalk.

In some embodiments, since the isolation structure material 116 is etched after forming the spacer layer 132, the isolation structure material 116 under the spacer layer 132 remains after the etching process 146. In some embodiments, the bottommost surface of the spacer layer 132 is higher than the bottommost surface of the topmost second semiconductor material layer 106.

Next, the first semiconductor material layers 104 are removed and gaps are formed between the first semiconductor material layers 104. More specifically, the second semiconductor material layers 106 exposed by the gaps form nanostructures 106, and the nanostructures 106 are configured to function as channel regions in the resulting semiconductor devices 10a in accordance with some embodiments.

The first semiconductor material layers 104 may be removed by performing one or more etching processes. The etching process may include a selective wet etching process, such as APM (e.g., ammonia hydroxide-hydrogen peroxide-water mixture) etching process. The wet etching process uses etchants such as ammonium hydroxide (NH₄OH), TMAH, ethylenediamine pyrocatechol (EDP), and/or potassium hydroxide (KOH) solutions.

Next, a gate structures 150 are formed surrounding the nanostructures 106 and over the nanostructures 106, as shown in FIGS. 2G-1, 2G-2, 2G-3, 2G-4 and 2G-5 in accordance with some embodiments. Gate structures 150 are formed surrounding the nanostructures 106 to form gate-all-around (GAA) transistor structures. Therefore, the gate control ability may be enhanced.

The gate structures 150 may be a multi-layered structure. Each of the gate structures 150 may include an interfacial layer, a gate dielectric layer, a work function layer, and a gate electrode layer.

The interfacial layer may be formed around the nanostructures 106 and on the exposed portions of the base fin structures. The interfacial layer may be made of silicon oxide, and the interfacial layer may be formed by thermal oxidation.

The gate dielectric layer may be formed over the interfacial layer, so that the nanostructures 106 are surrounded (e.g. wrapped) by the gate dielectric layer. In addition, the gate dielectric layer also covers the sidewalls of the spacer layers 132 and the inner spacers 134 in accordance with some embodiments. The gate dielectric layer may be made of one or more layers of dielectric materials, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other applicable high-k dielectric materials, or a combination thereof. The gate dielectric layer may be formed using CVD, ALD, other applicable methods, or a combination thereof.

The work function layers may be conformally formed over the nanostructure 106. The work function layers may be multi-layer structures. The work function layers may be made of a metal material. The metal material of the work function layers may include an N-work-function metal. The N-work-function metal may include tungsten (W), copper (Cu), titanium (Ti), silver (Ag), aluminum (Al), titanium aluminum alloy (TiAl), titanium aluminum nitride (TiAlN), tantalum carbide (TaC), tantalum carbon nitride (TaCN), tantalum silicon nitride (TaSiN), manganese (Mn), zirconium (Zr), or a combination thereof. The metal material of the work function layer may include a P-work-function metal. The P-work-function metal may include titanium nitride (TiN), tungsten nitride (WN), tantalum nitride (TaN), ruthenium (Ru) or a combination thereof. The work function layers may be formed by using CVD, ALD, other applicable methods, or a combination thereof.

Next, a gate electrode layer may be formed over the work function layer. The gate electrode layer may be made of one or more layers of conductive material, such as aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, another suitable material, or a combination thereof. The gate electrode layer may be formed using CVD, ALD, electroplating, another applicable method, or a combination thereof. After the gate electrode layer is formed, a planarization process such as CMP or an etch-back process may be performed.

In some embodiments, the gate structure 150 surrounding the nanostructures 106 has a length L1, and the gate structure 150 has a length L2 between the fin structures 110. In some embodiments, the length L2 of the gate structure 150 between the fin structures 110 is substantially equal to the length L1 of the gate structure 150 surrounding the nanostructures 106.

Next, a gate isolation structure 152 is formed between the fin structures 110, as shown in FIGS. 2H-1, 2H-2, 2H-3, 2H-4 and 2H-5 in accordance with some embodiments. The gate structure 150 may be cut by the gate isolation structure 152. In some embodiments, the gate isolation structure 152 directly contacts the isolation structure material 116.

A mask layer may be formed over the gate structure 150. The mask layer may be a hard mask layer made of SiN, SOC, other suitable materials, or a combination thereof. The mask layer may be formed using spin coating, LPCVD, PECVD, PVD, ALD, or other suitable processes.

Afterwards, an opening may be formed in the mask layer, the gate structure 150, and the isolation structure 116 between the fin structures 110. Next, the gate isolation structure material may be deposited in the opening. Afterwards, a removal process, such as CMP or other suitable processes, may be performed to remove excess gate isolation structure material from over the gate structure 150, such that upper surfaces of the gate isolation structure material are substantially level with upper surfaces of the gate structure 150. Therefore, the gate isolation structure 152 is formed in the opening.

The gate isolation structure 152 may provide isolation between the fin structures 110. The gate isolation structure 152 may be made of SiN, SiCN, SiCON, other suitable materials, or a combination thereof. The position of the gate isolation structure 152 may be defined by a patterning process, and the gate isolation structure 152 may be formed by CVD, such as LPCVD or plasma-enhanced CVD (PECVD).

Next, an opening is formed in the ILD structure 140, and a metal semiconductor compound layer may be formed over the source/drain epitaxial structure 136. The metal semiconductor compound layer may reduce the contact resistance between the source/drain epitaxial structure 136 and the subsequently formed contact structure over the source/drain epitaxial structure 136. The metal semiconductor compound layer may be made of titanium silicide (TiSi₂), nickel silicide (NiSi), cobalt silicide (CoSi), or other suitable low-resistance materials. The metal semiconductor compound layer may be formed over the source/drain epitaxial structure 136 by forming a metal layer over the source/drain epitaxial structure 136 first. The metal layer may react with the source/drain epitaxial structure 136 in an annealing process and a metal semiconductor compound layer may be produced. Afterwards, the unreacted metal layer may be removed in an etching process and the metal semiconductor compound layer may be left.

Next, a barrier layer may be conformally formed over the bottom surface and the sidewalls of the opening. Afterwards, the barrier layer may be etched back. The barrier layer remains over the bottom surface of the opening. The barrier layer may be formed before filling the conductive material in the opening to prevent the conductive material from diffusing out. The barrier layer may also serve as an adhesive or glue layer. The material of the barrier layer may be TiN, Ti, other applicable materials, or a combination thereof. The barrier layer may be formed by depositing the barrier layer materials by a physical vapor deposition process (PVD) (e.g., evaporation or sputtering), an atomic layer deposition process (ALD), an electroplating process, other applicable processes, or a combination thereof.

Afterwards, a contact structure 154 is formed into the opening over the source/drain epitaxial structure 136, as shown in FIGS. 2H-1, 2H-2, 2H-3, 2H-4 and 2H-5 in accordance with some embodiments. The contact structure 154 may be made of a metal material (e.g., Co, Ni, W, Ti, Ta, Cu, Al, Ru, Mo, TiN, TaN, and/or a combination thereof), metal alloys, poly-Si, other applicable conductive materials, or a combination thereof. The contact structure 154 may be formed by a chemical vapor deposition process (CVD), a physical vapor deposition process (PVD), (e.g., evaporation or sputter), an atomic layer deposition process (ALD), an electroplating process, another suitable process, or a combination thereof to deposit the conductive materials of the contact structure 154, and then a planarization process such as a chemical mechanical polishing (CMP) process or an etch back process is optionally performed to remove excess conductive materials. After the planarization process, the top surface of the contact structure 154 may be level with the top surface of the spacer layers 132.

In some embodiments, the contact structure 154 formed over adjacent source/drain epitaxial structures 136 are separated from each other.

By etching back the isolation structure material 116 after removing the dummy gate structure 122, the remaining isolation structure material 116 formed under the spacer layers 132 may reduce the amount of parasitic capacitance. The height of the dummy gate structure 122 is also lowered. Therefore, the dummy gate structure 122 may not collapse, due to the lower aspect ratio during the etching process.

Many variations and/or modifications may be made to the embodiments of the disclosure. FIGS. 3A-1, 3A-2, 3A-3, 3B-1, 3B-2, 3B-3, 3C-1, 3C-2, 3C-3, 3C-4, 3C-5, 3D-1, 3D-2, 3D-3, 3D-4 and 3D-5 are cross-sectional representations of various stages of forming a semiconductor device structure 10b, in accordance with some embodiments of the disclosure. Some processes or devices are the same as, or similar to, those described in the embodiments above, and therefore the descriptions of these processes and devices are not repeated herein. The difference from the embodiments described above is that, as shown in FIGS. 3A-1, 3A-2 and 3A-3 in accordance with some embodiments, the isolation structure material 116 is recessed after deposition.

The isolation structure material 116 is etched back, and the remaining isolation structure material 116 surrounds the base portion of the fin structures 110, as shown in FIGS. 3A-1, 3A-2 and 3A-3, in accordance with some embodiments. In some embodiments, the isolation material is etched back using a dry etching process.

Next, a refill material 160 is deposited over the isolation structure material 116 between the fin structures 110, as shown in FIGS. 3B-1, 3B-2 and 3B-3 in accordance with some embodiments. The refill material 160 may be made of SiN, SiO₂, SiON, SiCN, SiCON, SiCO, high-k dielectric materials such as HfO, AlO, etc.

In some embodiments, the dielectric constant of the isolation structure material 116 is lower than the dielectric constant of the refill material 160. The film quality may be better, and isolation may be enhanced. In some embodiments, the dielectric constant of the refill material 160 is lower than the dielectric constants of the spacer layer 132 and the inner spacer 134. In some embodiments, the dielectric constant of the refill material 160 is greater than 3.9. In some embodiments, the refill material 160 and the isolation structure material 116 are made of different materials.

The refill material 160 may be deposited by a deposition process, such as a chemical vapor deposition (CVD) process (e.g. a flowable CVD (FCVD) process), a spin-on-glass process, or another applicable process. In some embodiments, the top surface of the refill material 160 is substantially level with the top surface of the semiconductor stack 107.

Afterwards, the dummy gate structure 122 is formed over the fin structure 110, and the spacer layers 132 is formed over the opposite sides of the dummy gate structure 132. The source/drain epitaxial structure 136 is formed over opposite sides of the dummy gate structures 122. The etch stop layer 138 is formed over the source/drain epitaxial structure 136, and the ILD structure 140 is formed over the source/drain epitaxial structure 136, as shown in FIGS. 3C-1, 3C-2, 3C-3, 3C-3, 3C-4 and 3C-5 in accordance with some embodiments. The processes and materials for forming the dummy gate structure 122, the spacer layers 132, the source/drain epitaxial structure 136, the etch stop layer 138 and the ILD structure 140 may be the same as, or similar to, those used to form the dummy gate structure 122, the spacer layers 132, the source/drain epitaxial structure 136, the etch stop layer 138, and the ILD structure 140 in the previous embodiments. For the purpose of brevity, the descriptions of these processes and materials are not repeated herein.

In some embodiments, the isolation material 116 and the etch stop layer 138 are separated by the refill material 160.

After removing the dummy gate structure 122, the refill material 160 exposed by the trench 144 are etched back using an etching process 146, and the refill material 160 surrounding the fin structure 110 is removed, as shown in FIGS. 3C-1, 3C-2, 3C-3, 3C-3, 3C-4 and 3C-5 in accordance with some embodiments. The etching process 146 may remove the refill material 160 and stop on the isolation structure material 116. In some embodiments, the etching process 146 is a dry etching process.

In some embodiments, since the refill material 160 is etched after forming the spacer layer 132, the refill material 160 under the spacer layer 132 remains after the etching process 146.

Later, the gate structure 150 is formed in the trench 144, the gate isolation structure 152 is formed between the fin structures 110, and the contact structures 154 are formed over the source/drain epitaxial structures 136, as shown in FIGS. 3D-1, 3D-2, 3D-3, 3D-3, 3D-4 and 3D-5 in accordance with some embodiments. The processes and materials for forming the gate structure 150, the fin structures 110, and the contact structures 154 may be the same as, or similar to, those used to form the gate structure 150, the fin structures 110, and the contact structures 154 in the previous embodiments. For the purpose of brevity, the descriptions of these processes and materials are not repeated herein.

By etching back the refill material 160 after removing the dummy gate structure 122, the remaining refill material 160 and the isolation structure material 116 formed under the spacer layers 132 may reduce the parasitic capacitance. The height of the dummy gate structure 122 is also lowered. Therefore, the dummy gate structure 122 may not collapse, due to the lower aspect ratio during the etching process. The refill material 160 may provide better film quality.

Many variations and/or modifications may be made to the embodiments of the disclosure. FIGS. 4A-1, 4A-2, 4A-3, 4A-4, 4A-5, 4B-1, 4B-2, 4B-3, 4B-4, 4B-5, 4C-1, 4C-2, 4C-3, 4C-4 and 4C-5 are cross-sectional representations of various stages of forming a semiconductor device structure 10c, in accordance with some embodiments of the disclosure. Some processes or devices are the same as, or similar to, those described in the embodiments above, and therefore the descriptions of these processes and devices are not repeated herein. The difference from the embodiments described above is that, as shown in FIGS. 4A-1, 4A-2, 4A-3, 4A-4 and 4A-5 in accordance with some embodiments, while etching back the isolation structure material 116 after removing the dummy gate structure 122, less of the bottom portion of the isolation structure material 116 than the top portion of the isolation structure material 116 is laterally removed.

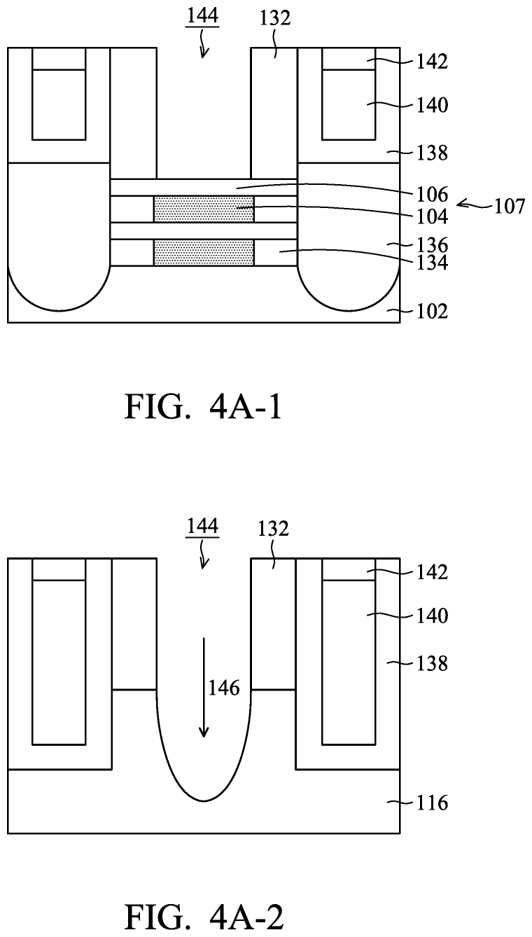

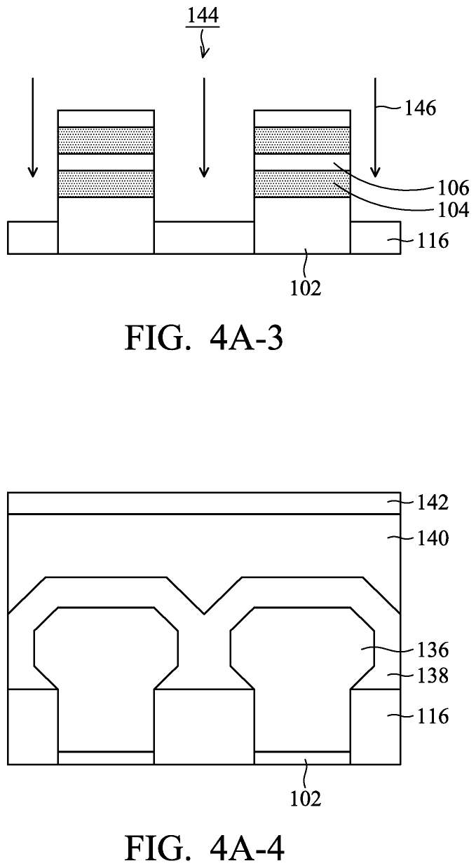

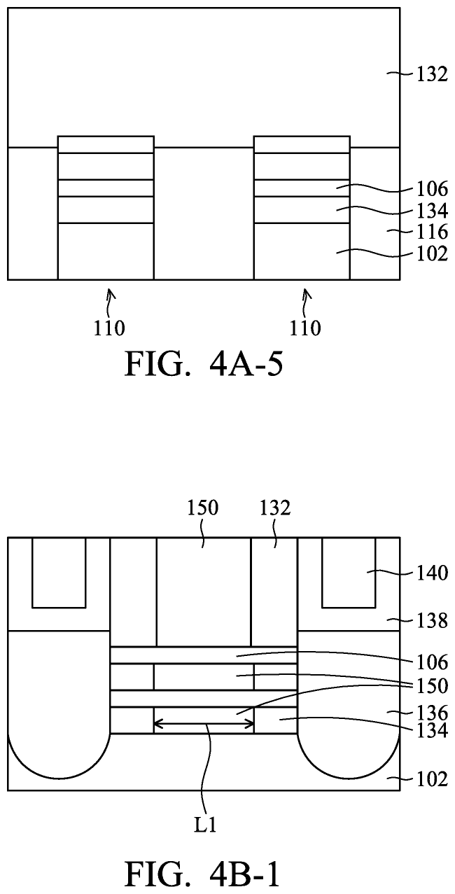

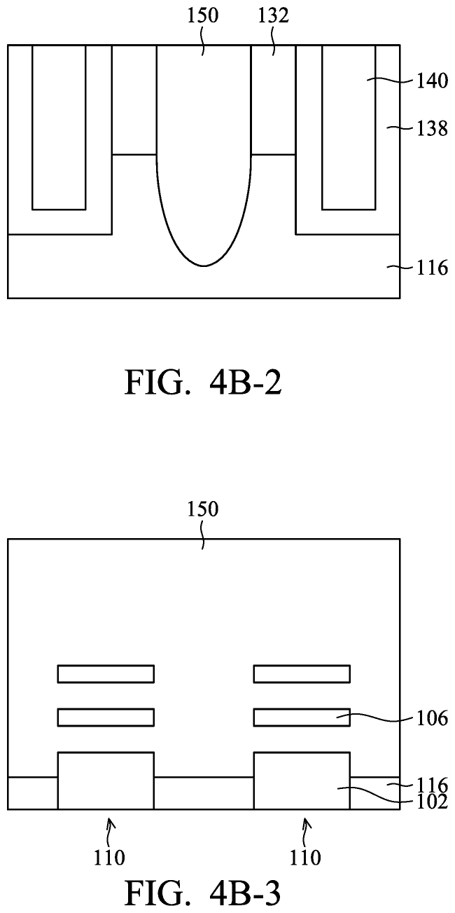

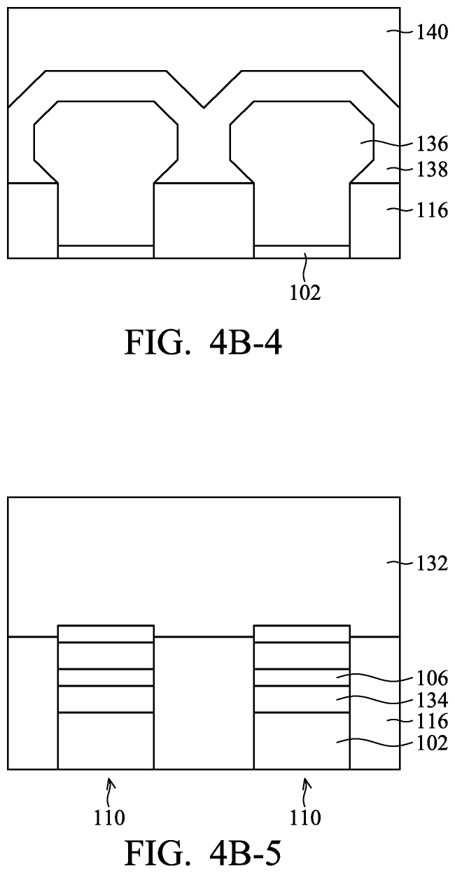

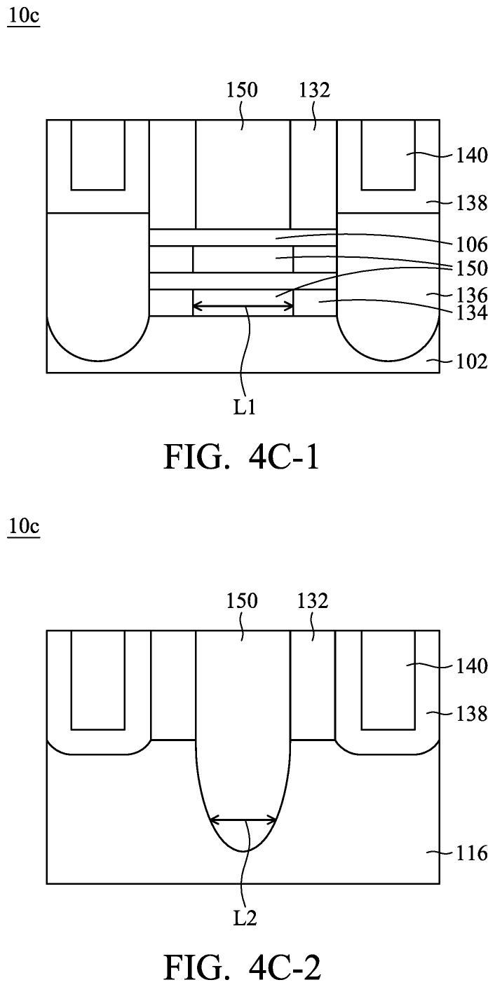

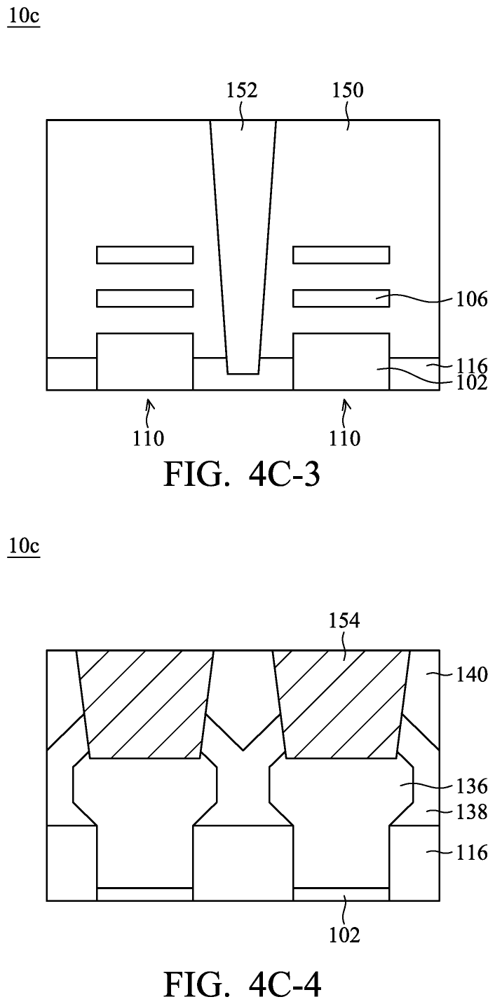

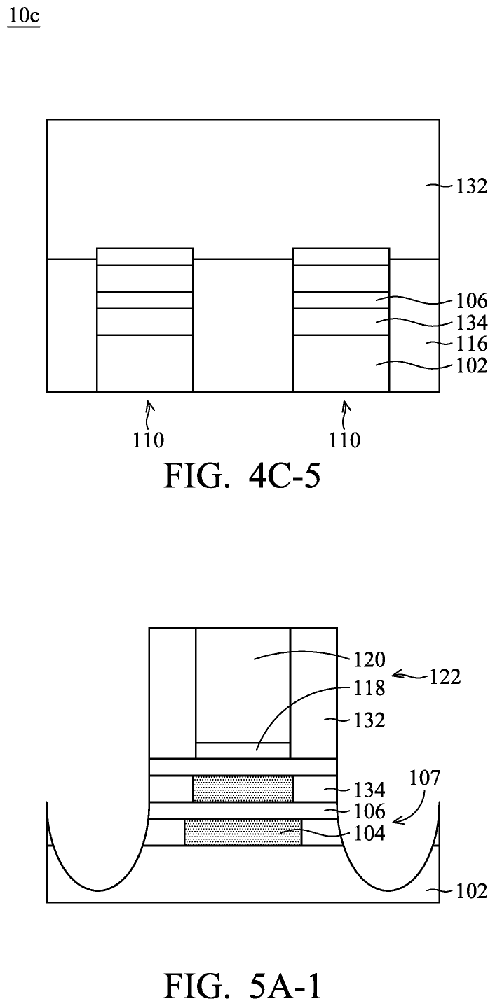

In some embodiments, the isolation structure material 116 between the spacer layers 132 has a curved top surface in a cross-sectional view between the fin structures 110, as shown in FIG. 4A-2 in accordance with some embodiments

Next, the gate structure 150 is formed in the trench 144, the gate isolation structure 152 is formed between the fin structures 110, and the contact structures 154 are formed over the source/drain epitaxial structures 136, as shown in FIGS. 4B-1, 4B-2, 4B-3, 4B-4, 4B-5, 4C-1, 4C-2, 4C-3, 4C-4 and 4C-5 in accordance with some embodiments.

In some embodiments, the bottom portion of the gate structure 150 over the isolation material 116 is narrower than the gate structure 150 wrapped around the second semiconductor layers 106. In some embodiments, the gate structure 150 surrounding the nanostructures 106 has a length L1, and the gate structure 150 has a length L2 between the fin structures 110. In some embodiments, the length L2 of the gate structure 150 between the fin structures 110 is less than the length L1 of the gate structure 150 surrounding the nanostructures 106. With a shorter length L2 of the gate structure 150 between the fin structures 110, the outer fringe parasitic capacitance between the contact structure 154 and the source/drain epitaxial structures 136 may be reduced. In addition, the gate structure 150 and the source/drain epitaxial structures 136 may not be short-circuited.

In some embodiments, the length L2 of the gate structure 150 is less than the length L1 of the gate structure 150 by a distance in a range of about 1 nm to about 6 nm. If the difference is too great, the length L2 of the gate structure 150 may be too short, and the dummy gate structure 122 surrounding the nanostructures 106 may remain. The electrical characteristics of the semiconductor structure 10c may be worse.

By etching back the isolation structure material 116 after removing the dummy gate structure 122, the remaining isolation structure material 116 formed under the spacer layers 132 may reduce the parasitic capacitance. The height of the dummy gate structure 122 is also lowered. Therefore, the dummy gate structure 122 may not collapse, due to the lower aspect ratio during the etching process. The length L2 of the gate structure 150 between the fin structures 110 is less than the length L1 of the gate structure 150 surrounding the nanostructures 106. The parasitic capacitance may be reduced, and the gate structure 150 and the source/drain epitaxial structures 136 may not be short-circuited.

Many variations and/or modifications may be made to the embodiments of the disclosure. FIGS. 5A-1, 5A-2, 5A-3, 5A-4, 5A-5, 5B-1, 5B-2, 5B-3, 5B-4, 5B-5, 5C-1, 5C-2, 5C-3, 5C-4 and 5C-5 are cross-sectional representations of various stages of forming a semiconductor device structure 10d, in accordance with some embodiments of the disclosure. Some processes or devices are the same as, or similar to, those described in the embodiments above, and therefore the descriptions of these processes and devices are not repeated herein. The difference from the embodiments described above is that, as shown in FIGS. 5A-1, 5A-2, 5A-3, 5A-4 and 5A-5 in accordance with some embodiments, the first semiconductor layers 104 surrounding the second semiconductor layers 106 have different lengths.

When the first semiconductor material layers 104 being laterally etched from the source/drain opening to form a recess, the upper first semiconductor material layers 104 may be etched more than the lower first semiconductor material layers 104. Therefore, the upper inner spacer 134 formed in the recess may be wider than the lower inner spacer 134 formed in the recess.

Next, the dummy gate structure 122 may be removed, and the isolation structure material 116 may be etched back. In some embodiments, less of the bottom portion of the isolation structure material 116 than the top portion of the isolation structure material 116 is laterally removed, as shown in FIGS. 5B-1, 5B-2, 5B-3, 5B-4 and 5B-5.

Next, the gate structure 150 is formed in the trench 144, the gate isolation structure 152 is formed between the fin structures 110, and the contact structures 154 are formed over the source/drain epitaxial structures 136, as shown in FIGS. 5C-1, 5C-2, 5C-3, 5C-4 and 5C-5 in accordance with some embodiments.

In some embodiments, the lower portion of the gate structure 150 surrounding the nanostructures 106 is longer than the upper portion of the gate structure 150 surrounding the nanostructures 106.

In some embodiments, the length L3 of the higher gate structure 150 surrounding the nanostructure 106 is less than the length L1 of the lower gate structure 150 surrounding the nanostructure 106. In some embodiments, the length L2 of the gate structure 150 between the fin structures 110 is less than the length L3 of the higher gate structure 150 surrounding the nanostructure 106.

In some embodiments, the length L2 of the gate structure 150 is less than the length L1 of the gate structure 150 by a distance in a range of about 1 nm to about 6 nm. If the difference is too great, the length L2 of the gate structure 150 may be too short, and the dummy gate structure 122 surrounding the nanostructures 106 may remain. The electrical characteristics of the semiconductor structure 10c may be worse.

In some embodiments, the length L3 of the gate structure 150 is less than the length L1 of the gate structure 150 by a distance in a range of about 1 nm to about 6 nm. If the difference is too great, the capacitance caused by the longer bottom gate structure 150 may be increased.

By etching back the isolation structure material 116 after removing the dummy gate structure 122, the remaining isolation structure material 116 formed under the spacer layers 132 may reduce the parasitic capacitance. The height of the dummy gate structure 122 is also lowered. Therefore, the dummy gate structure 122 may not collapse, due to the lower aspect ratio during the etching process. The length L2 of the gate structure 150 between the fin structures 110 is less than the length L1 of the gate structure 150 surrounding the nanostructures 106. The parasitic capacitance may be reduced, and the gate structure 150 and the source/drain epitaxial structures 136 may not be short-circuited. In addition, the length L3 of the higher gate structure 150 surrounding the nanostructure 106 is less than the length L1 of the lower gate structure 150 surrounding the nanostructure 106.

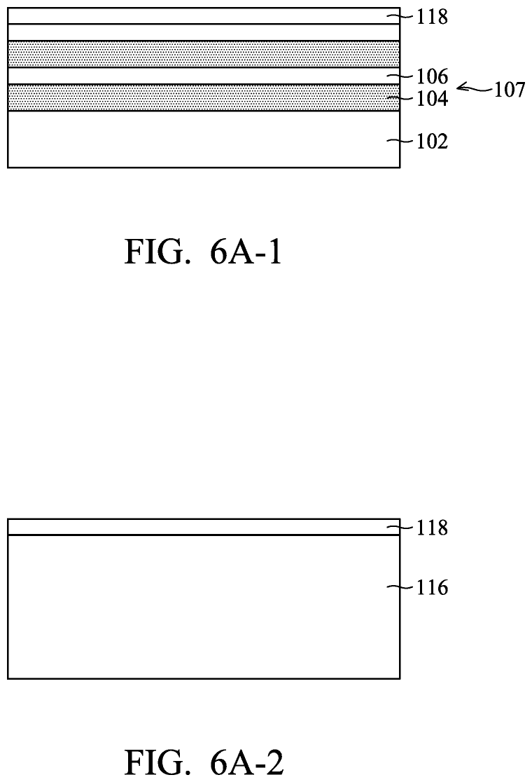

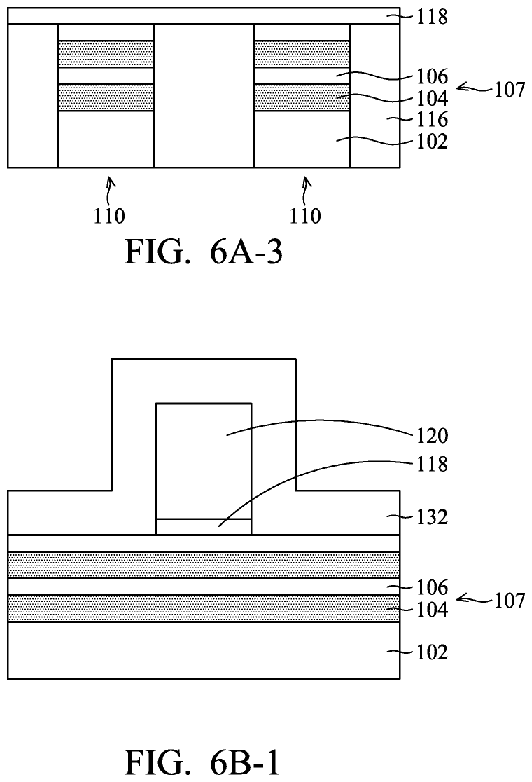

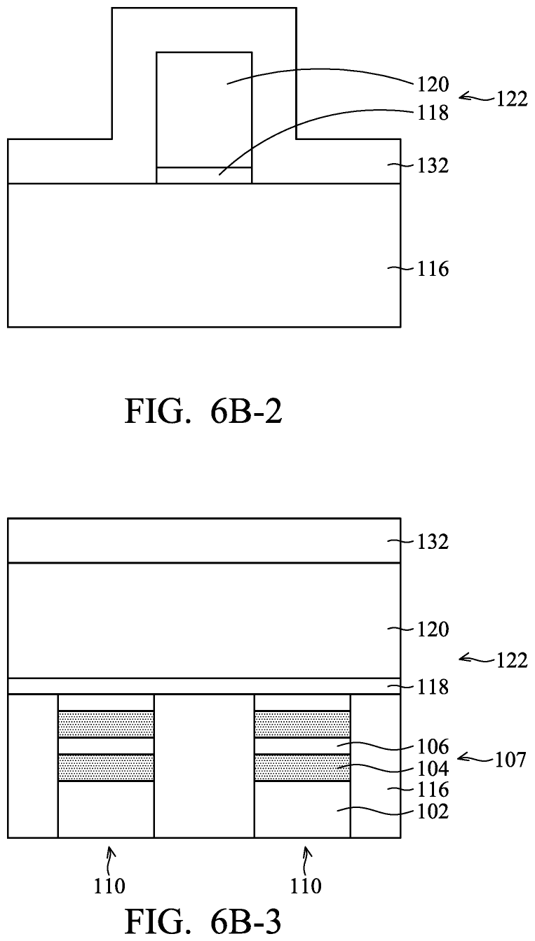

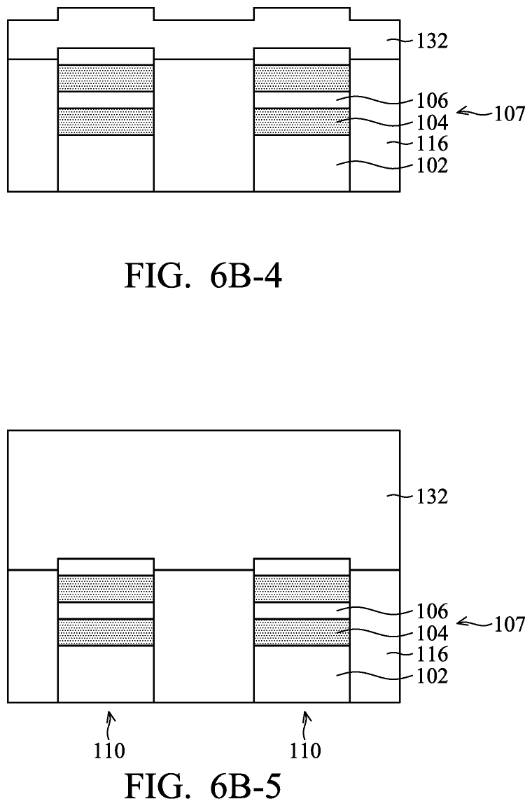

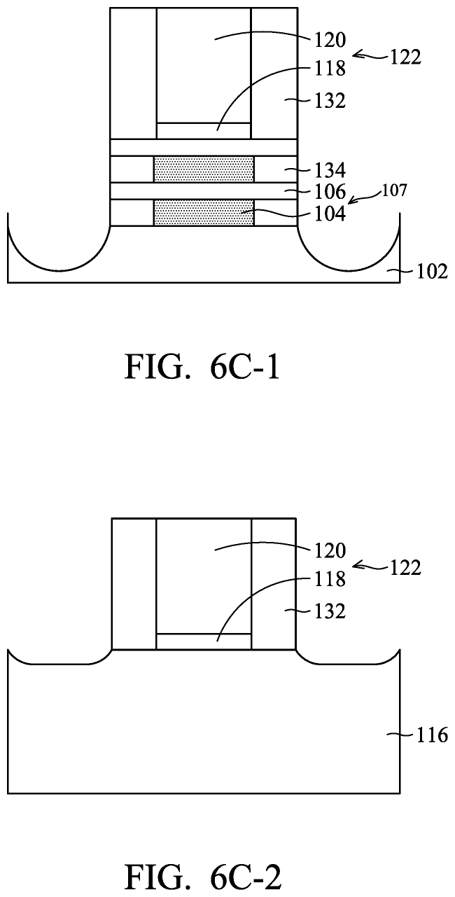

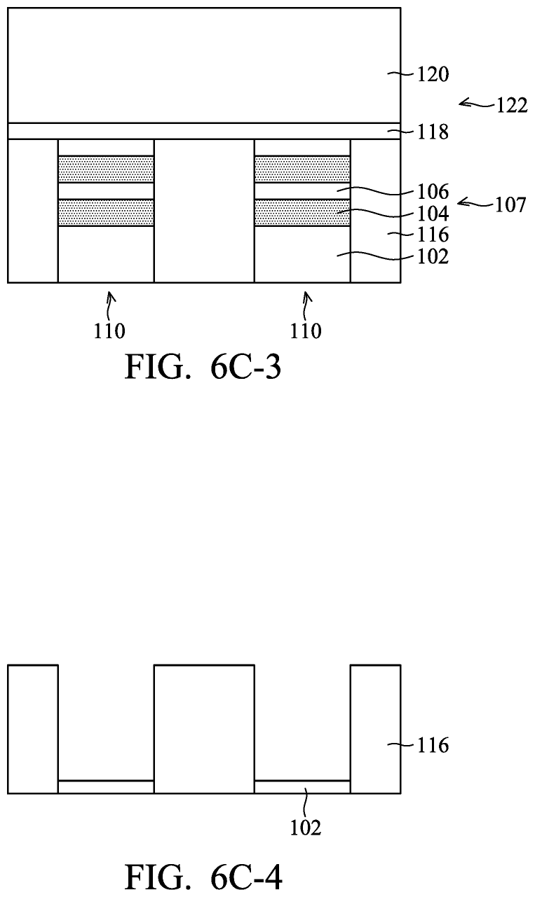

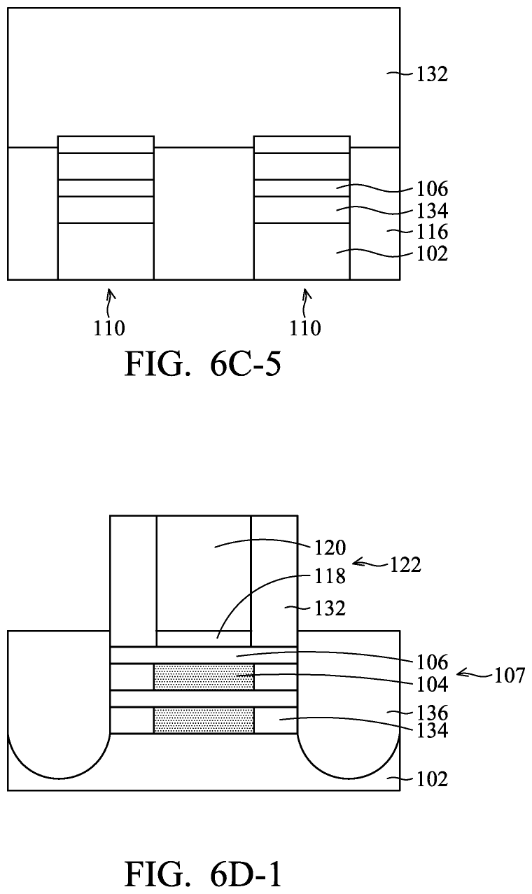

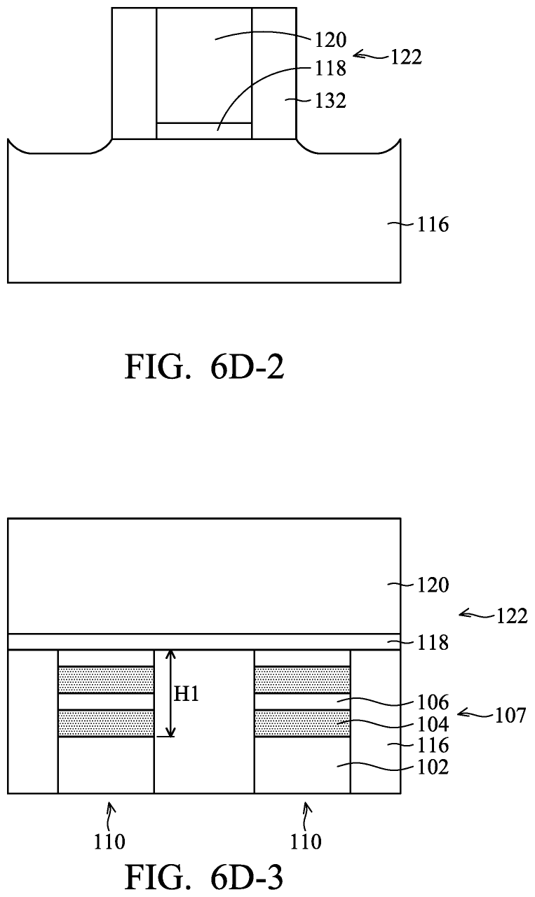

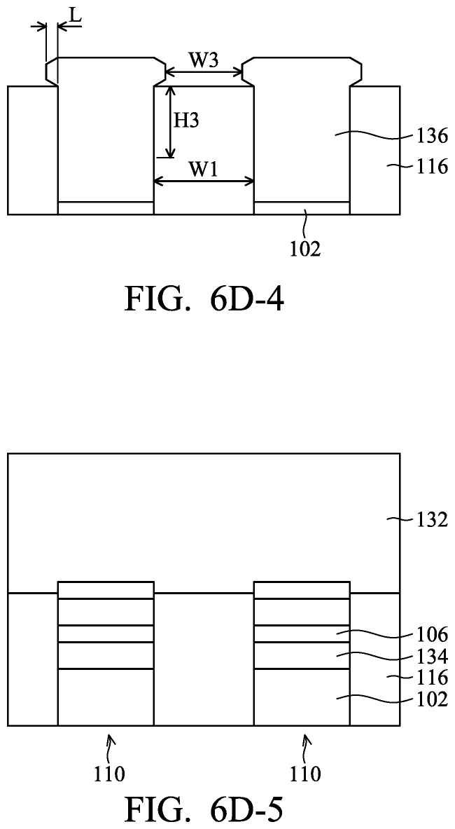

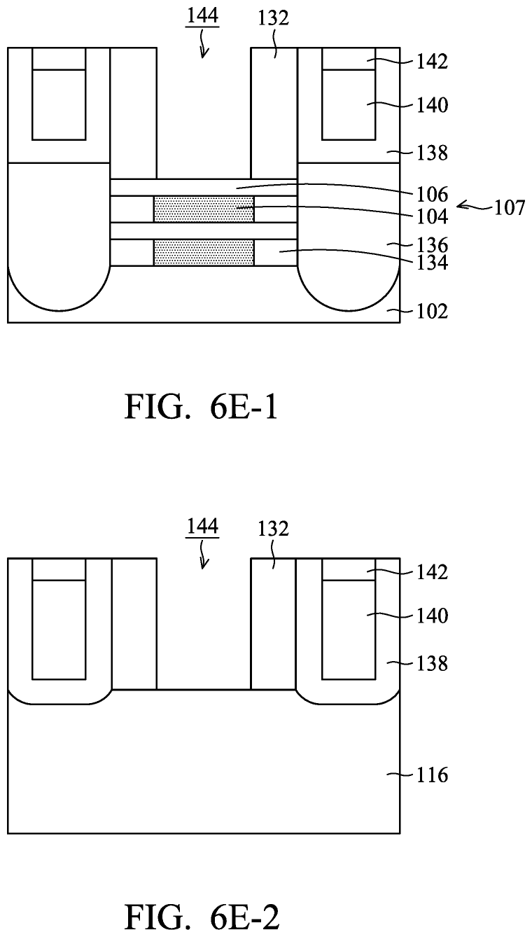

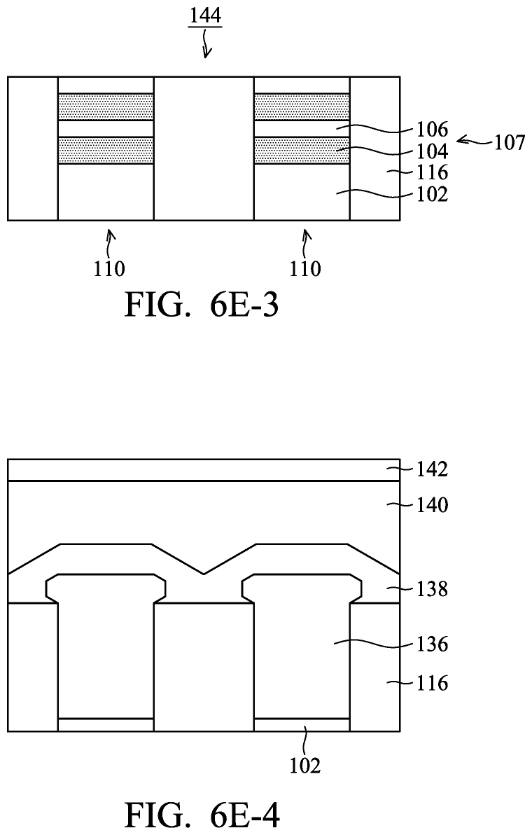

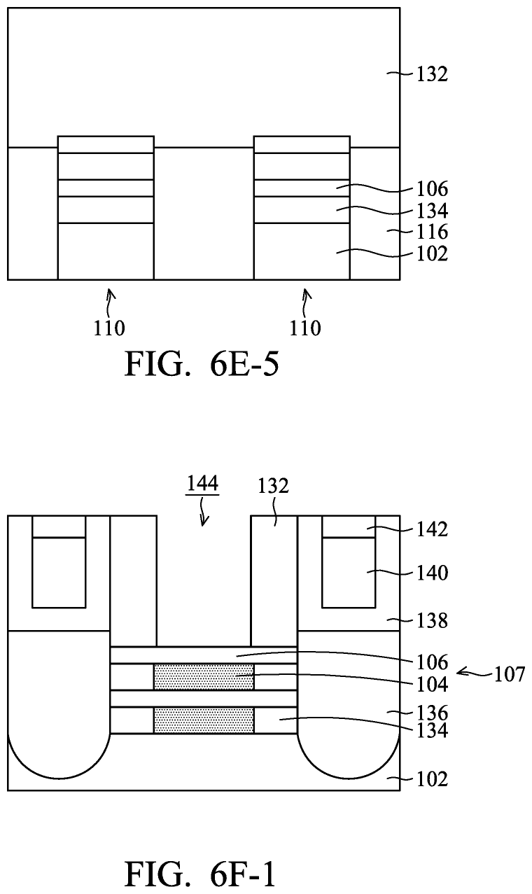

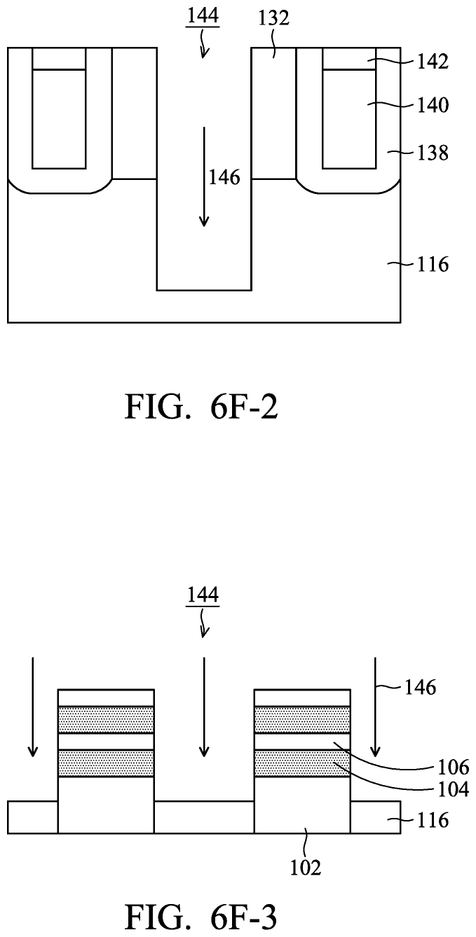

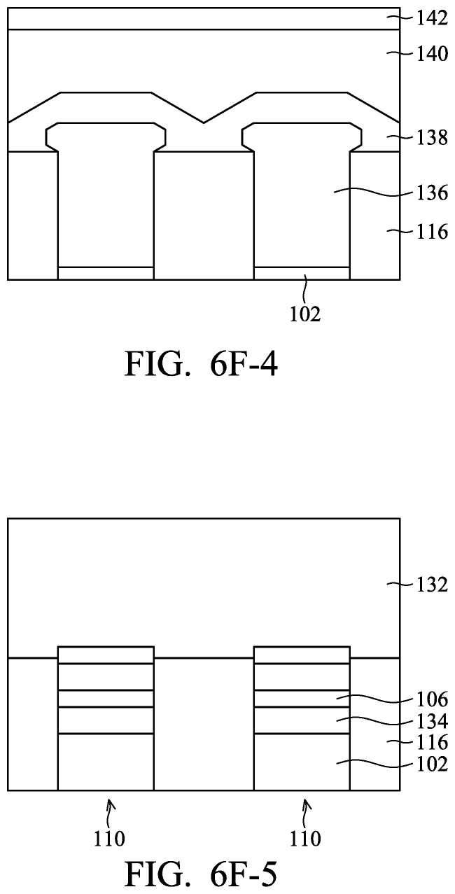

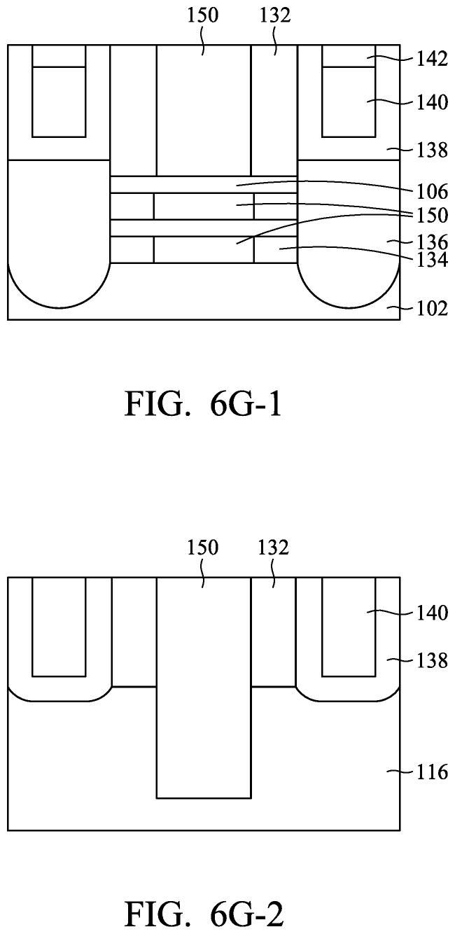

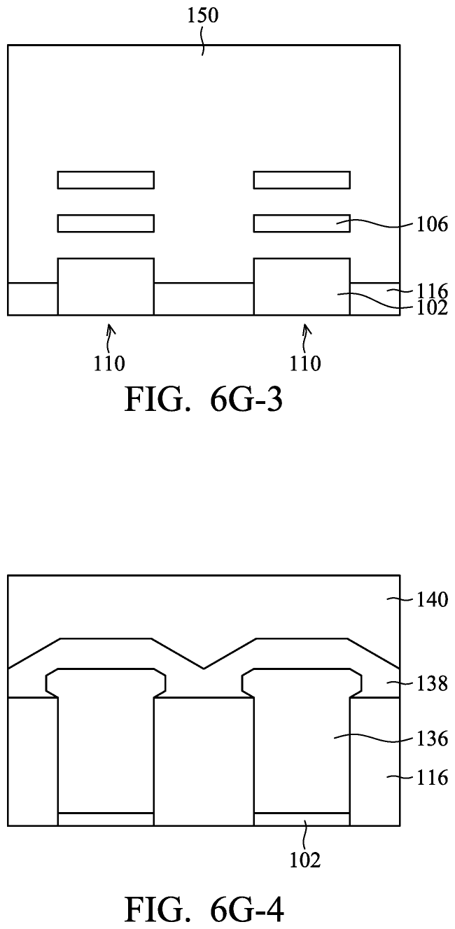

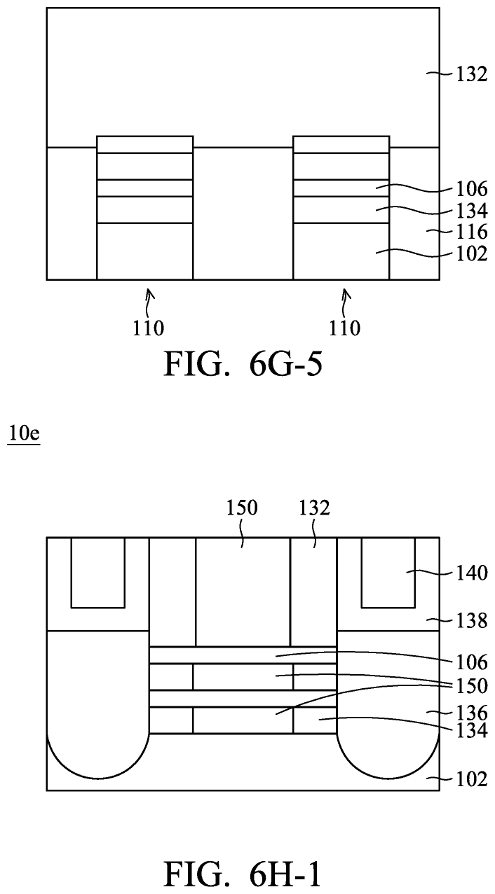

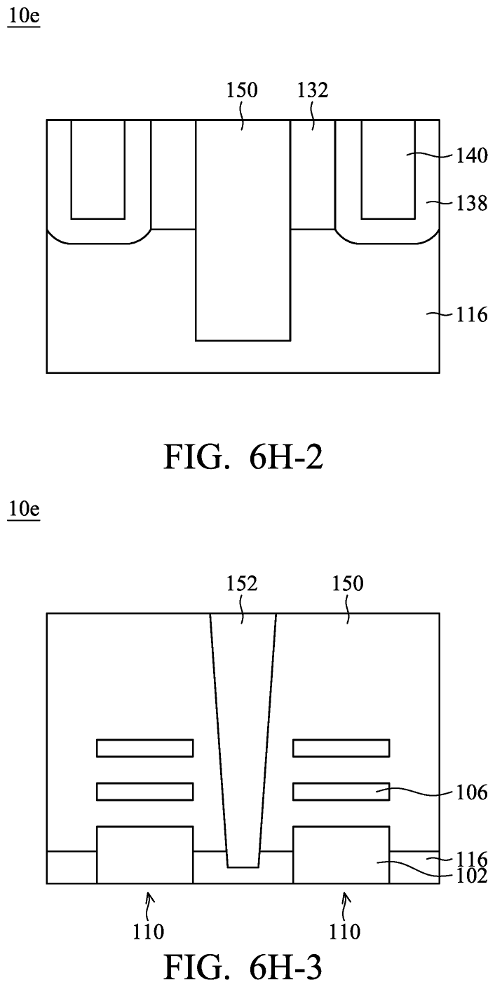

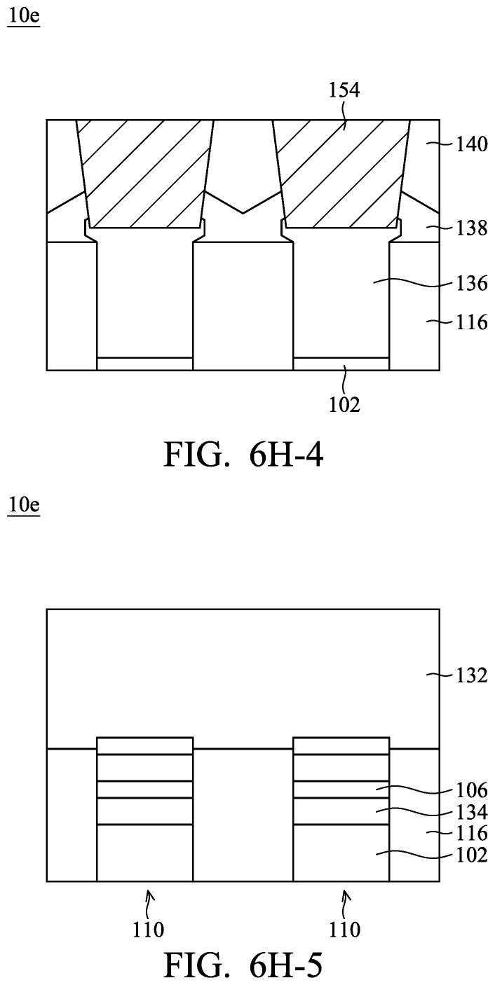

Many variations and/or modifications may be made to the embodiments of the disclosure. FIGS. 6A-1, 6A-2, 6A-3, 6B-1, 6B-2, 6B-3, 6B-4, 6B-5, 6C-1, 6C-2, 6C-3, 6C-4, 6C-5, 6D-1, 6D-2, 6D-3, 6D-4, 6D-5, 6E-1, 6E-2, 6E-3, 6E-4, 6E-5, 6F-1, 6F-2, 6F-3, 6F-4, 6F-5, 6G-1, 6G-2, 6G-3, 6G-4, 6G-5, 6H-1, 6H-2, 6H-3, 6H-4 and 6H-5 are cross-sectional representations of various stages of forming a semiconductor device structure 10e, in accordance with some embodiments of the disclosure. Some processes or devices are the same as, or similar to, those described in the embodiments above, and therefore the descriptions of these processes and devices are not repeated herein. The difference from the embodiments described above is that, as shown in FIGS. 6C-1, 6C-2, 6C-3, 6C-4 and 6C-5 in accordance with some embodiments, the isolation structure material 116 is less recessed compared to the previous embodiments when forming the source/drain opening.

In some embodiments, the spacer layers 132 formed over the isolation structure material 116 is removed, and the top surface of the isolation structure material 116 is exposed in a cross-sectional view outside the dummy gate structure 122 along the extending direction of the dummy gate structure 122 (i.e., the Y direction).

In some embodiments, when forming the source/drain opening, the isolation structure material 116 is less recessed since the dry etching rate of the isolation structure material 116 is low. In some embodiments, the isolation structure material 116 is not consumed during the dry etching process.

Next, the source/drain epitaxial structures 136 are formed in the source/drain opening, as shown in FIGS. 6D-1, 6D-2, 6D-3, 6D-4 and 6D-5 in accordance with some embodiments. In some embodiments, the semiconductor stack 107 has a height of H1, and the isolation structure material 116 above the bottom surface of the semiconductor stack 107 has a height of H3. In some embodiments, the ratio of height H3 to height H1 is in a range of about 0.5 to about 1. If the ratio of height H3 to height H1 is too low, source/drain epitaxial structure 136 may be laterally grown and adjacent source/drain epitaxial structure 136 may be merged.

In some embodiments, the shortest distance W3 is the distance between adjacent source/drain epitaxial structures 136, and the distance W1 is the distance between adjacent source/drain epitaxial structures 136 in the isolation structure material 116. In some embodiments, the ratio of distance W3 to distance W1 is in a range of about 0.5 to about 1. If the ratio of the distance W3 to the distance W1 is too low, adjacent source/drain epitaxial structure 136 may be merged.

In some embodiments, the source/drain epitaxial structures 136 are laterally extended by a distance L. In some embodiments, the lateral distance L is less than 3 nm. If the lateral distance L is too great, adjacent source/drain epitaxial structure 136 may be merged.

Next, the ILD structure 140 is formed over the source/drain epitaxial structure 136, and the dummy gate structure 122 is removed, as shown in FIGS. 6E-1, 6E-2, 6E-3, 6E-4 and 6E-5 in accordance with some embodiments. In some embodiments, the bottom surface of the ILD structure 140 is higher than a top surface of the isolation material 116.

Afterwards, the isolation structure material 116 is etched back by the etching process 146, as shown in FIGS. 6F-1, 6F-2, 6F-3, 6F-4 and 6F-5 in accordance with some embodiments. Next, the gate structure 150 is formed in the trench 144, the gate isolation structure 152 is formed between the fin structures 110, and the contact structures 154 are formed over the source/drain epitaxial structures 136, as shown in FIGS. 6G-1, 6G-2, 6G-3, 6G-4, 6G-5, 6H-1, 6H-2, 6H-3, 6H-4 and 6H-5 in accordance with some embodiments.

In some embodiments, the middle portion at half height of the source/drain epitaxial structure 136 is surrounded by the isolation material 116, not by the contact etch stop layer 138.

By etching back the isolation structure material 116 after removing the dummy gate structure 122, the remaining isolation structure material 116 formed under the spacer layers 132 may reduce the parasitic capacitance. The height of the dummy gate structure 122 is also lowered. Therefore, the dummy gate structure 122 may not collapse, due to the lower aspect ratio during etching. Higher isolation structure material 116 may confine the growth of the source/drain epitaxial structures 136, and adjacent source/drain epitaxial structures 136 may not merge.

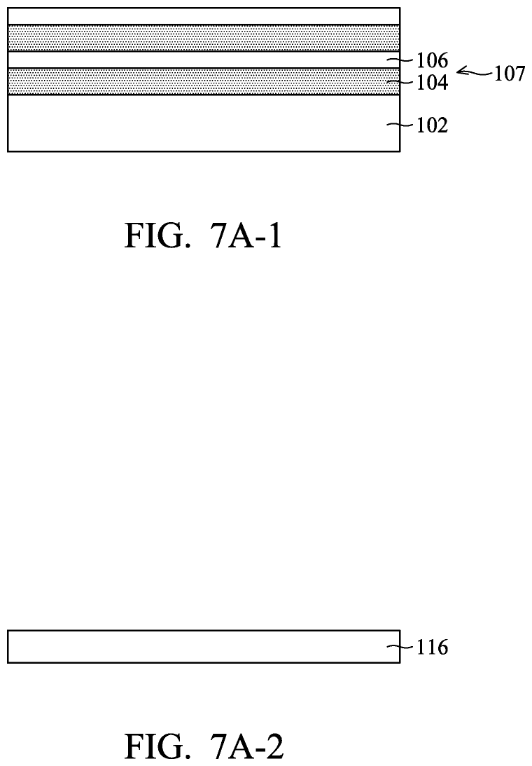

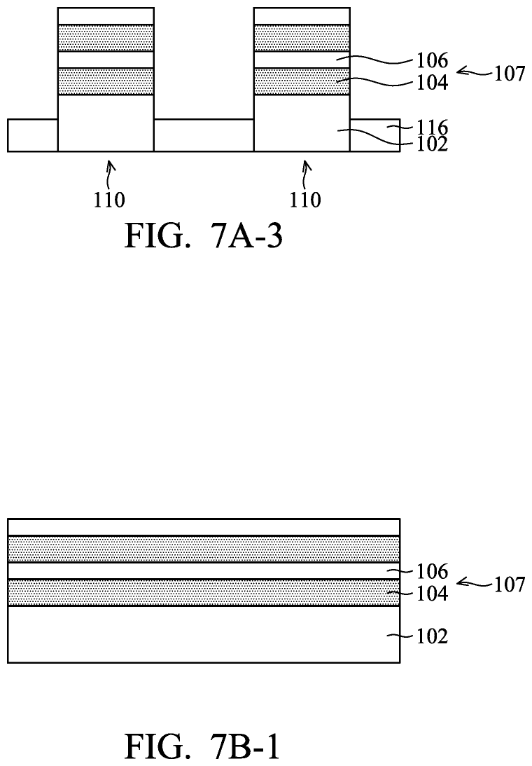

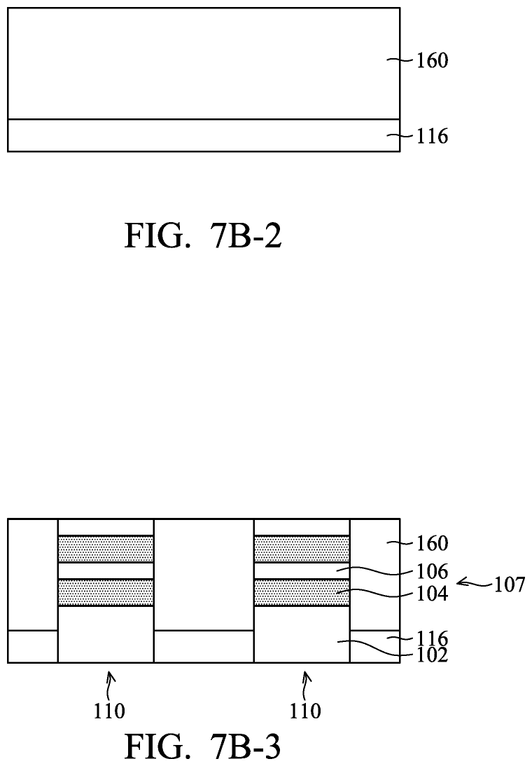

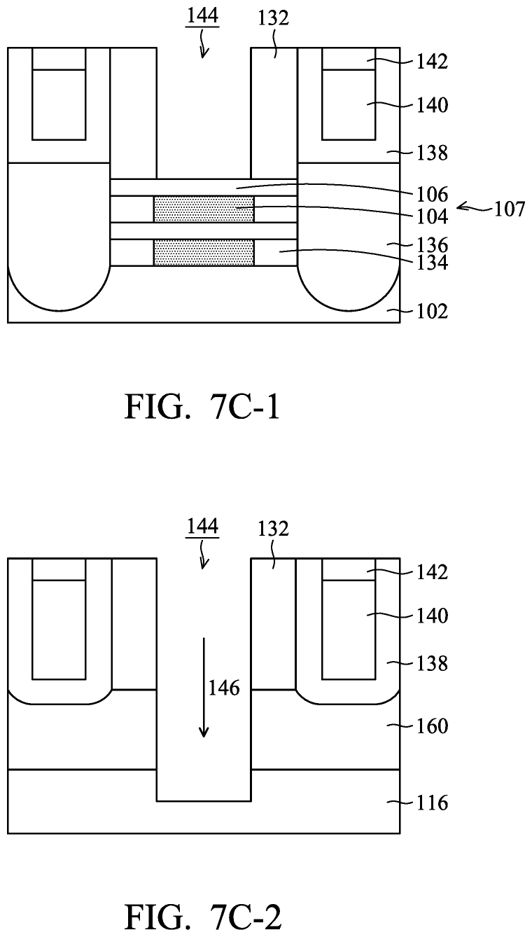

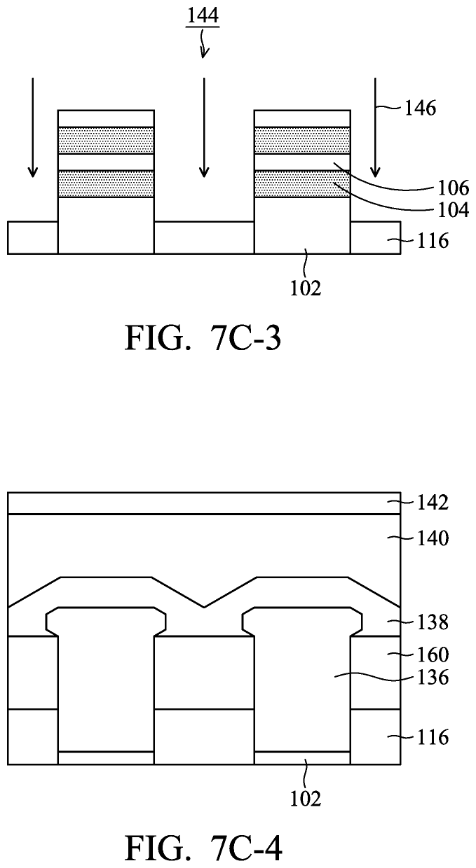

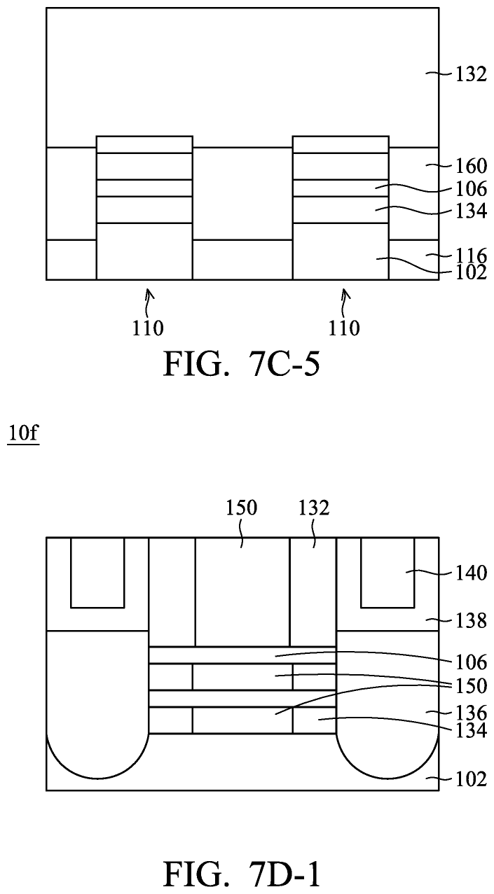

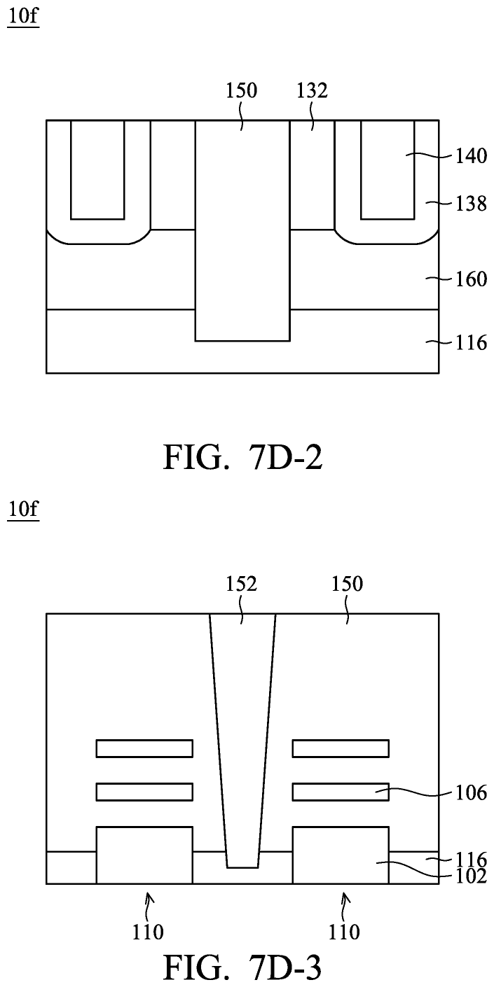

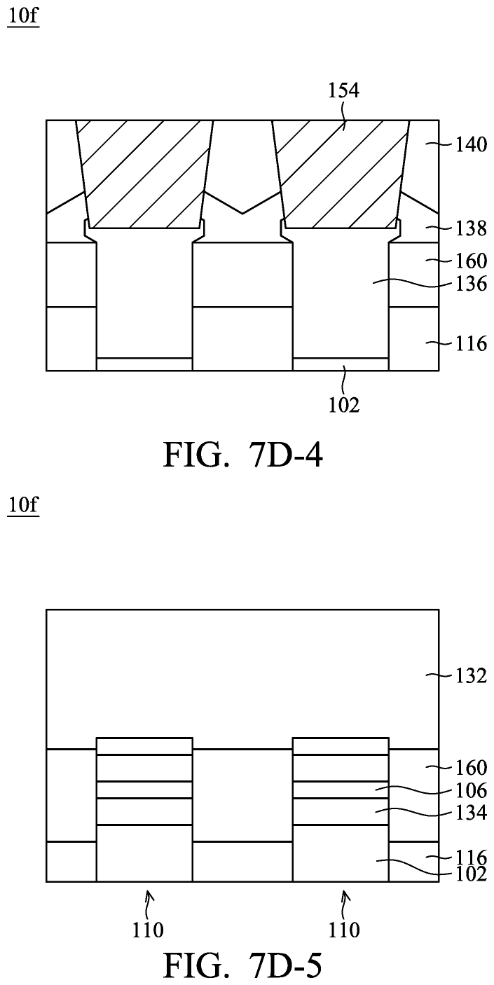

Many variations and/or modifications may be made to the embodiments of the disclosure. FIGS. 7A-1, 7A-2, 7A-3, 7B-1, 7B-2, 7B-3, 7C-1, 7C-2, 7C-3, 7C-4, 7C-5, 7D-1, 7D-2, 7D-3, 7D-4 and 7D-5 are cross-sectional representations of various stages of forming a semiconductor device structure 10f, in accordance with some embodiments of the disclosure. Some processes or devices are the same as, or similar to, those described in the embodiments above, and therefore the descriptions of these processes and devices are not repeated herein. The difference from the embodiments described above is that, as shown in FIGS. 7A-1, 7A-2, 7A-3, 7B-1, 7B-2 and 7B-3 in accordance with some embodiments, a refill material 160 is formed over the isolation structure material 116. In addition, the refill material 160 is less recessed compared to the previous embodiments when forming the source/drain opening.

Next, the source/drain epitaxial structures 136 are formed in the source/drain opening, and the refill material 160 is etched back, as shown in FIGS. 7C-1, 7C-2, 7C-3, 7C-4 and 7C-5 in accordance with some embodiments. Since the refill material 160 is less recessed, the refill material 160 over the isolation structure material 116 is higher. The growth of the source/drain epitaxial structures 136 may be confined, and adjacent source/drain epitaxial structure 136 may be not merged.

Later, the gate structure 150 is formed in the trench 144, the gate isolation structure 152 is formed between the fin structures 110, and the contact structures 154 are formed over the source/drain epitaxial structures 136, as shown in FIGS. 7D-1, 7D-2, 7D-3, 7D-4 and 7D-5 in accordance with some embodiments.

In some embodiments, the middle portion at half height of the source/drain epitaxial structure 136 is surrounded by the refill material 160, not by the contact etch stop layer 138.

By etching back the refill material 160 after removing the dummy gate structure 122, the remaining refill material 160 under the spacer layers 132 may reduce the parasitic capacitance. The height of the dummy gate structure 122 is also lowered. Therefore, the dummy gate structure 122 may not collapse, due to the lower aspect ratio during etching. A higher refill material 160 may confine the growth of the source/drain epitaxial structures 136, and adjacent source/drain epitaxial structures 136 may not merge.

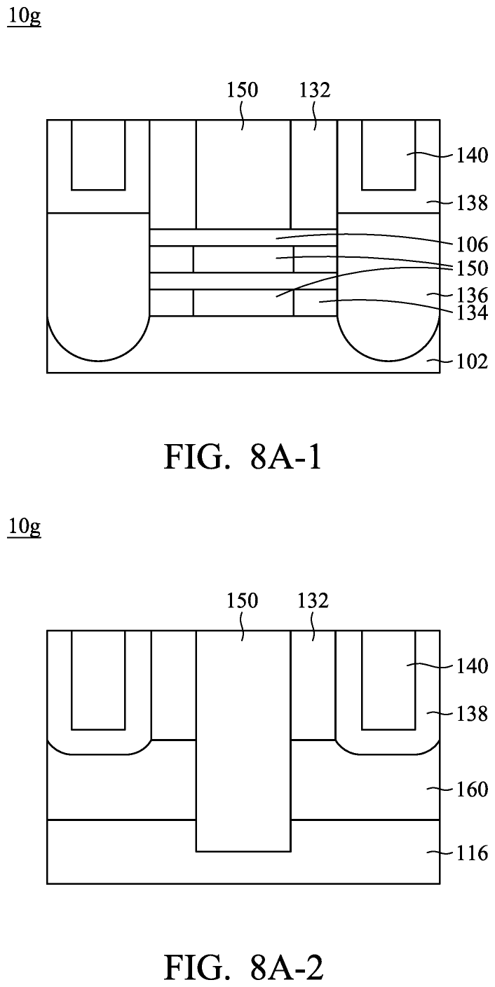

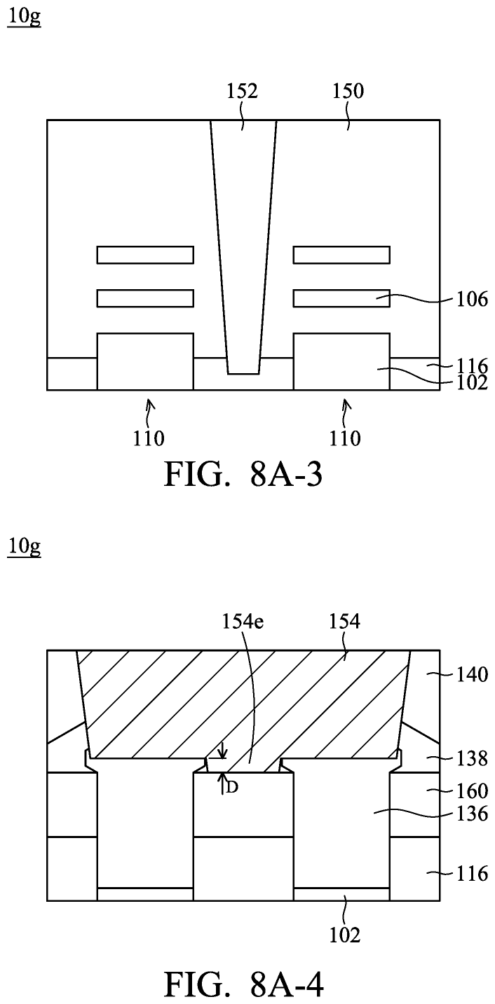

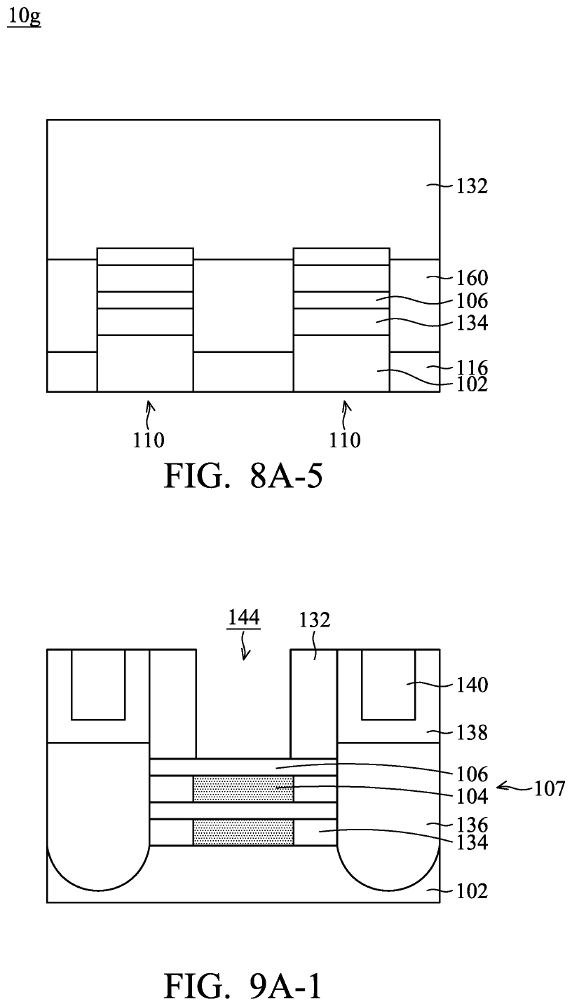

Many variations and/or modifications may be made to the embodiments of the disclosure. FIGS. 8A-1, 8A-2, 8A-3, 8A-4 and 8A-5 are cross-sectional representations of various stages of forming a semiconductor device structure 10g, in accordance with some embodiments of the disclosure. Some processes or devices are the same as, or similar to, those described in the embodiments above, and therefore the descriptions of these processes and devices are not repeated herein. The difference from the embodiments described above is that, as shown in FIGS. 8A-1, 8A-2, 8A-3, 8A-4 and 8A-5 in accordance with some embodiments, the contact structure 154 formed over adjacent source/drain epitaxial structures 136 are merged.

An opening may be formed in the ILD structure 140, and adjacent source/drain epitaxial structures 136 and the refill material 160 between the source/drain epitaxial structures 136 are exposed in the opening. The etching process of forming the opening may stop over the refill material 160.

Afterwards, a contact structure 154 is formed into the opening over the source/drain epitaxial structure 136, as shown in FIGS. 2H-1, 2H-2, 2H-3, 2H-4 and 2H-5 in accordance with some embodiments. In some embodiments, the contact structure 154 has an extending portion 154e protruding between adjacent source/drain epitaxial structures. In some embodiments, the extending portion 154e of the contact structure 154 is in direct contact with the refill material 160. In some embodiments, the extending portion 154e of the contact structure 154 has a depth D. The depth D of the extending portion 154e of the contact structure 154 is less than 5 nm. The parasitic capacitance may be lowered.

By etching back the refill material 160 after removing the dummy gate structure 122, the remaining refill material 160 under the spacer layers 132 may reduce the parasitic capacitance. The height of the dummy gate structure 122 is also lowered. Therefore, dummy gate structure 122 may not collapse, due to the lower aspect ratio during etching. The contact structure 154 formed over adjacent source/drain epitaxial structures 136 may be merged with an extending portion 154e stop over the refill material 160. The parasitic capacitance may be reduced.

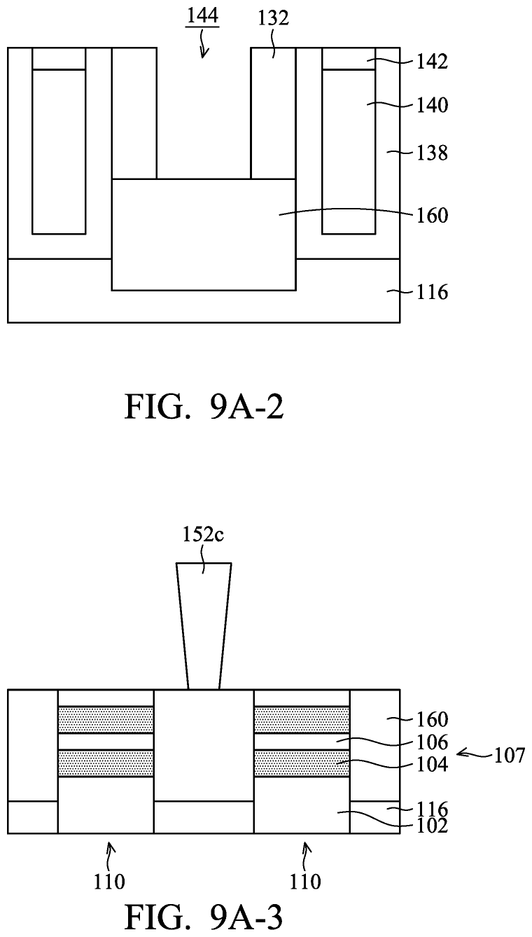

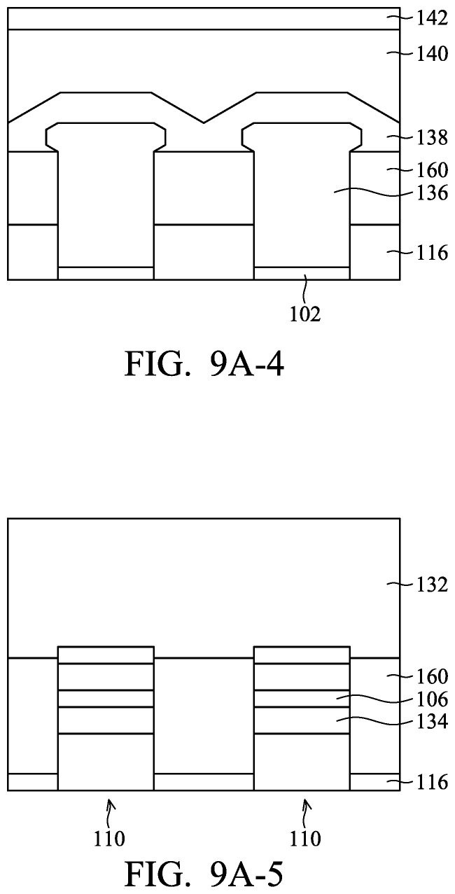

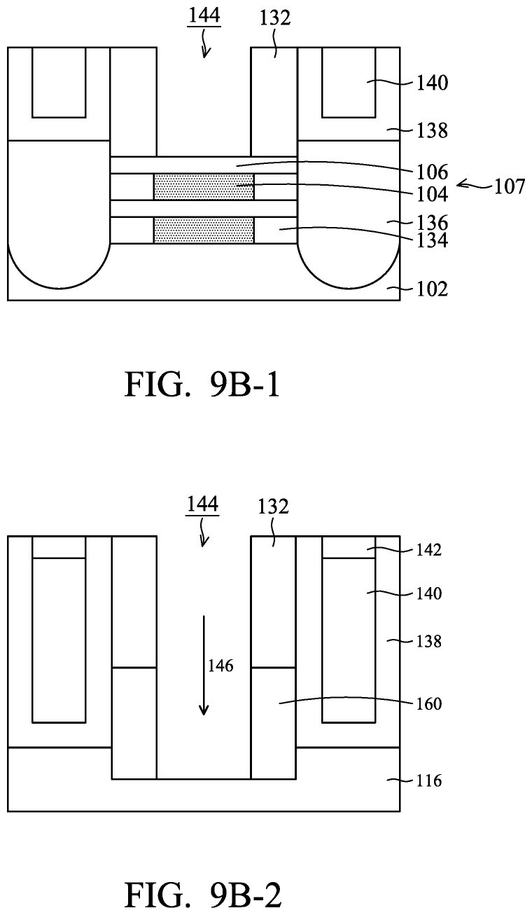

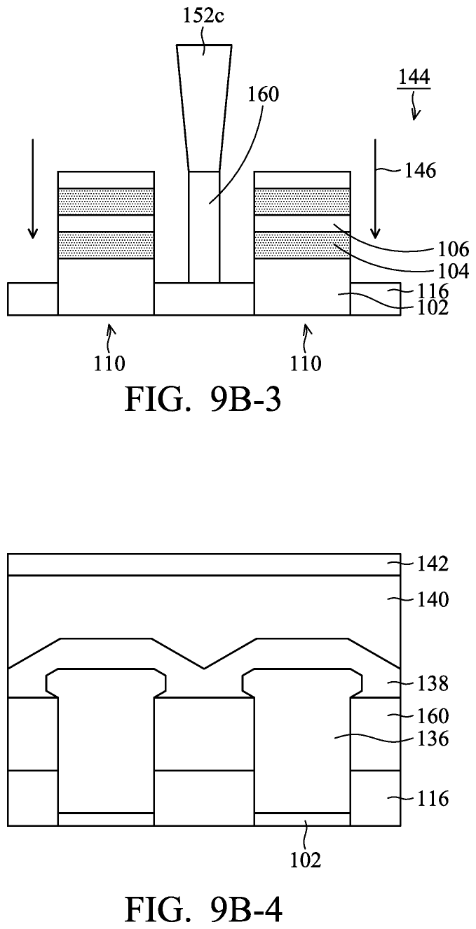

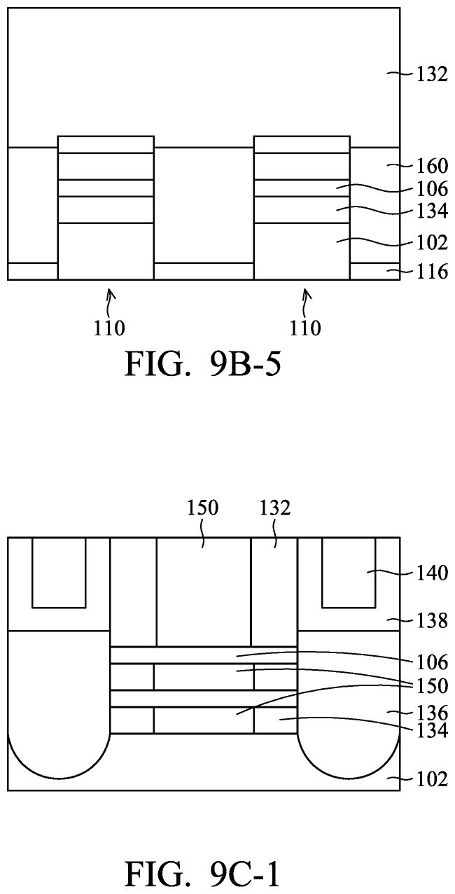

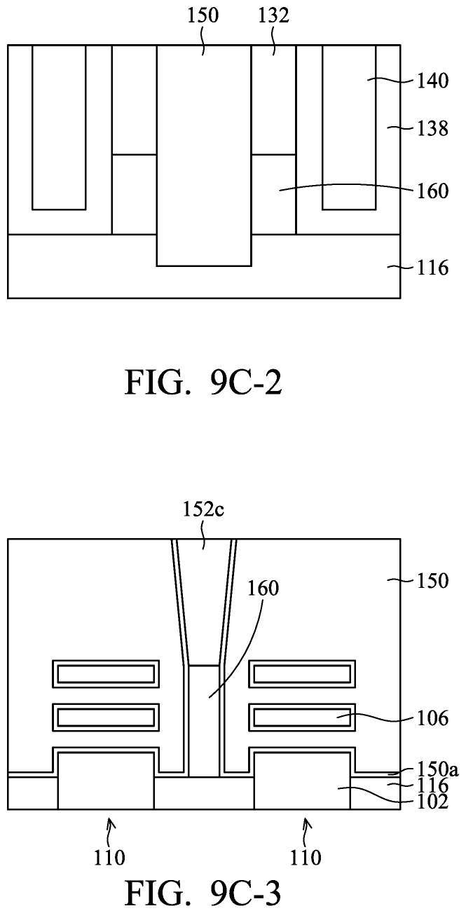

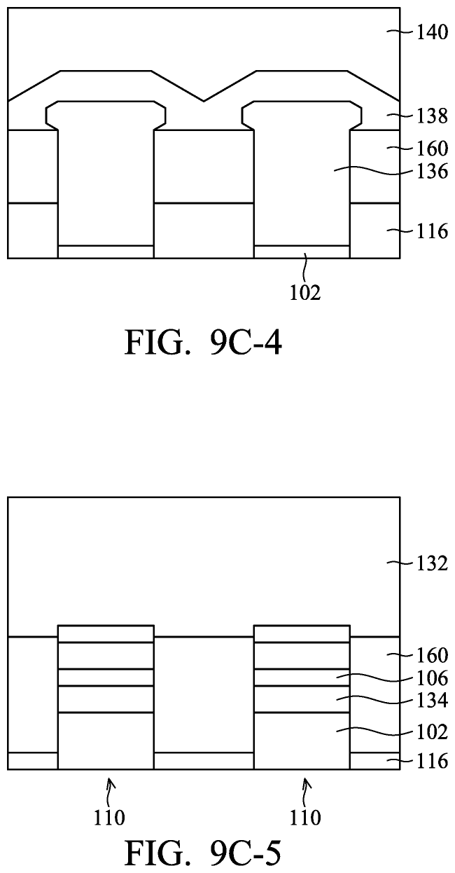

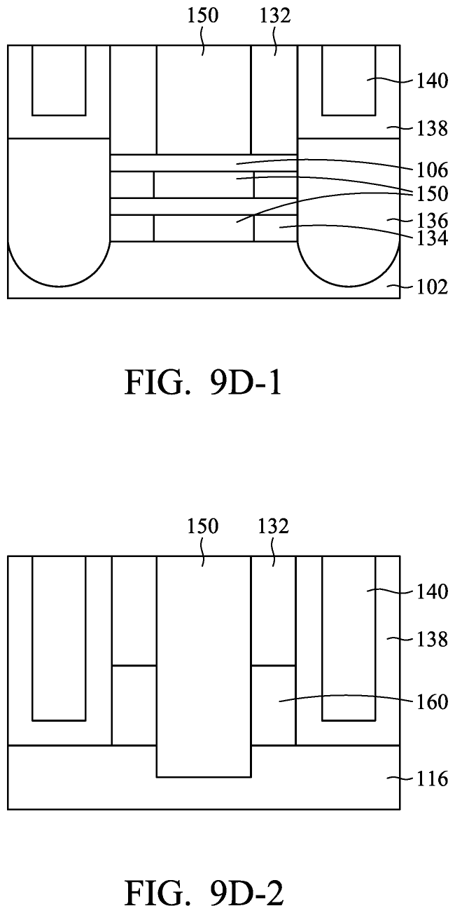

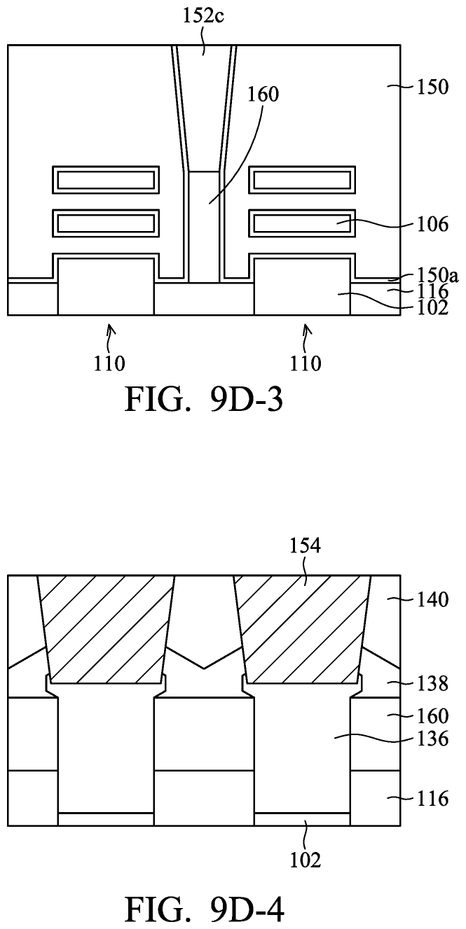

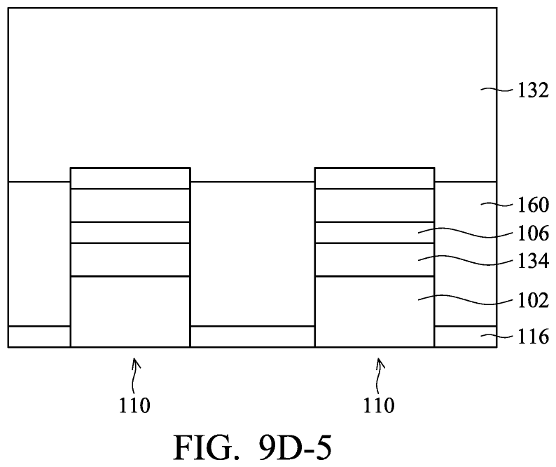

Many variations and/or modifications may be made to the embodiments of the disclosure. FIGS. 9A-1, 9A-2, 9A-3, 9A-4, 9A-5, 9B-1, 9B-2, 9B-3, 9B-4, 9B-5, 9C-1, 9C-2, 9C-3, 9C-4, 9C-5, 9D-1, 9D-2, 9D-3, 9D-4 and 9D-5 are cross-sectional representations of various stages of forming a semiconductor device structure 10h, in accordance with some embodiments of the disclosure. Some processes or devices are the same as, or similar to, those described in the embodiments above, and therefore the descriptions of these processes and devices are not repeated herein. The difference from the embodiments described above is that, as shown in FIGS. 9A-1, 9A-2, 9A-3, 9A-4, 9A-5 in accordance with some embodiments, a gate isolation structure 152c is formed over the refill material 160 cutting off the dummy gate structure 122.

After forming the dummy gate structure 122, the gate isolation structure 152c may be formed in the dummy gate structure 122 over the refill material 160. Later, the dummy gate structure 122 is removed, and the gate isolation structure 152c remains over the refill material 160, as shown in FIGS. 9A-1, 9A-2, 9A-3, 9A-4 and 9A-5 in accordance with some embodiments.

The gate isolation structure 152c may be made of oxide, such as SiO₂, SiOCN, SiON, or the like. The gate isolation structure 152c may also be made of a high k dielectric material, such as HfO₂, ZrO₂, HfAlOₓ, HfSiOₓ, Al₂O₃, or the like. The gate isolation structure 152c may be formed by performing ALD, CVD, PVD, another suitable process, or a combination thereof.

After the dummy gate structure 122 is removed, the refill material 160 is etched back, as shown in FIGS. 9B-1, 9B-2, 9B-3, 9B-4 and 9B-5 in accordance with some embodiments. The gate isolation structure 152c may be a hard mask, and the refill material 160 under the gate isolation structure 152c remains between the fin structures 110.

Later, the gate structure 150 is formed in the trench 144, as shown in FIGS. 9C-1, 9C-2, 9C-3, 9C-4 and 9C-5 in accordance with some embodiments. In some embodiments, the gate isolation structure 152c and the underlying refill material 160 isolates the gate structure 150 surrounding different fin structures 110. In some embodiments, the gate dielectric layer 150a forms over the sidewalls of the gate isolation structure 152c and the underlying refill material 160.

Next, the contact structures 154 are formed over the source/drain epitaxial structures 136, as shown in FIGS. 9D-1, 9D-2, 9D-3, 9D-4 and 9D-5 in accordance with some embodiments.

By etching back the refill material 160 after removing the dummy gate structure 122, the remaining refill material 160 under the spacer layers 132 may reduce the parasitic capacitance. The height of the dummy gate structure 122 is also lowered. Therefore, dummy gate structure 122 may not collapse, due to the lower aspect ratio during etching. The gate structures 150 may be isolated by forming a gate isolation structure 152c over the refill material 160.

As described previously, the isolation structure material 116 may be etched back after removing the dummy gate structure 122. Therefore, the isolation structure material 116 that remains under the spacer layers 132 may reduce the parasitic capacitance. The dummy gate structure 122 may not collapse, due to the lower height of the dummy gate structure 122. In some embodiments as shown in FIGS. 3B-1, 3B-2 and 3B-3, the refill material 160 is formed over the isolation structure material 116, and the film quality and the isolation is better. In some embodiments as shown in FIGS. 4C-1, 4C-2 4C-3, 4C-4 and 4C-5, the outer gate length L2 is less than the inner gate length L1, and the capacitance is further reduced. In some embodiments as shown in FIGS. 5C-1, 5C-2 5C-3, 5C-4 and 5C-5, the bottom inner gate length L1 is greater than the top inner gate length L3. In some embodiments as shown in FIGS. 6D-1, 6D-2 6D-3, 6D-4 and 6D-5, the remaining isolation structure material 116 is higher, and the source/drain epitaxial structures 136 are separated. In some embodiments as shown in FIGS. 7C-1, 7C-2 7C-3, 7C-4 and 7C-5, the remaining refill material 160 is higher, and the source/drain epitaxial structures 136 are separated. In some embodiments as shown in FIGS. 8A-1, 8A-2 8A-3, 8A-4 and 8A-5, the contact structures 154 formed over adjacent source/drain epitaxial structures 136 are merged, and the extending portion 154e of the contact structures 154 reduce the capacitance. In some embodiments as shown in FIGS. 9B-1, 9B-2 9B-3, 9B-4 and 9B-5, the gate isolation structure 152c over the refill material 160 isolates the gate structure 150.

Embodiments of a semiconductor device structure and a method for forming the same are provided. The isolation structure material is etched back after removing the dummy gate structure, but it remains under the spacer layers. The capacitance may be reduced. Higher isolation structure material may confine the growth of the source/drain epitaxial structures, and adjacent source/drain epitaxial structures may not merge.

In some embodiments, a method for forming a semiconductor device structure is provided. The method for forming a semiconductor device structure includes forming fin structures over a substrate. The method for forming a semiconductor device structure also includes depositing an isolation material surrounding the fin structures. The method for forming a semiconductor device structure also includes forming a dummy gate structure across the fin structure. The method for forming a semiconductor device structure also includes growing source/drain epitaxial structures over opposite sides of the dummy gate structure. The method for forming a semiconductor device structure also includes removing the dummy gate structure. The method for forming a semiconductor device structure also includes recessing the isolation material after removing the dummy gate structure. The method for forming a semiconductor device structure also includes forming a gate structure over the isolation material.

In some embodiments, a method for forming a semiconductor device structure is provided. The method for forming a semiconductor device structure includes forming fin structures with first semiconductor layers and second semiconductor layers alternately disposed over a substrate. The method for forming a semiconductor device structure also includes forming an isolation material surrounding base portions of the fin structures. The method for forming a semiconductor device structure also includes forming a refill material over the isolation material. The method for forming a semiconductor device structure also includes forming a dummy gate structure across the fin structure. The method for forming a semiconductor device structure also includes forming spacer layers over opposite sides of the dummy gate structure. The method for forming a semiconductor device structure also includes removing the dummy gate structure to form a gate trench between the spacer layers. The method for forming a semiconductor device structure also includes removing the refill material exposed by the gate trench. The method for forming a semiconductor device structure also includes removing the first semiconductor layers. The method for forming a semiconductor device structure also includes forming a gate structure wrapped around the second semiconductor layers.

In some embodiments, a semiconductor device structure is provided. The semiconductor device structure includes fin structures with nanostructures formed over a substrate. The semiconductor device structure also includes an isolation material surrounding the fin structures. The semiconductor device structure also includes a gate structure surrounding the nanostructures and longitudinally oriented along a first direction. The semiconductor device structure also includes spacer layers formed over opposite sides of the gate structure. The semiconductor device structure also includes source/drain epitaxial structures formed at opposite sides of the gate structures in a second direction. The second direction is different from the first direction. The semiconductor device structure also includes a gate isolation structure formed between the fin structures. The semiconductor device structure also includes contact structures formed over the source/drain epitaxial structures. The bottommost surface of the spacer layers is higher than the bottommost surface of the topmost nanostructures in a cross-sectional view over the spacer layers along the first direction.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device structure, comprising:
forming fin structures over a substrate;
depositing an isolation material surrounding the fin structures;
forming a dummy gate structure across the fin structure;
growing source/drain epitaxial structures over opposite sides of the dummy gate structure;
removing the dummy gate structure;
recessing the isolation material after removing the dummy gate structure; and
forming a gate structure over the isolation material.

2. The method for forming the semiconductor device structure as claimed in claim 1, further comprising:
etching back the isolation material; and
depositing a refill material over the isolation material between the fin structures,
wherein the isolation material and the refill material are different materials.

3. The method for forming the semiconductor device structure as claimed in claim 2, wherein a dielectric constant of the isolation material is lower than a dielectric constant of the refill material.

4. The method for forming the semiconductor device structure as claimed in claim 1, further comprising:
forming contact structures over the source/drain epitaxial structures,
wherein the contact structures are separated from each other.

5. The method for forming the semiconductor device structure as claimed in claim 1, wherein less of a bottom portion of the isolation structure material than a top portion of the isolation structure material is laterally removed.

6. The method for forming the semiconductor device structure as claimed in claim 1, further comprising:
forming an interlayer structure over the source/drain epitaxial structures,
wherein a bottom surface of the interlayer structure is higher than a top surface of the isolation material.

7. A method for forming a semiconductor device structure, comprising:
forming fin structures with first semiconductor layers and second semiconductor layers alternately formed over a substrate;
forming an isolation material surrounding base portions of the fin structures;
forming a refill material over the isolation material;
forming a dummy gate structure across the fin structure;
forming spacer layers over opposite sides of the dummy gate structure;
removing the dummy gate structure to form a gate trench between spacer layers;
removing the refill material exposed by the gate trench;
removing the first semiconductor layers; and
forming a gate structure wrapped around the second semiconductor layers.

8. The method for forming the semiconductor device structure as claimed in claim 7, further comprising:
forming a gate isolation structure over the refill material cutting off the dummy gate structure.

9. The method for forming the semiconductor device structure as claimed in claim 7, further comprising:
forming source/drain epitaxial structures beside the spacer layers;
forming contact structures over the source/drain epitaxial structures,
wherein the contact structures over adjacent source/drain epitaxial structures are merged.

10. The method for forming the semiconductor device structure as claimed in claim 9, wherein the contact structures have an extending portion protruding between adjacent source/drain epitaxial structures.

11. The method for forming the semiconductor device structure as claimed in claim 10, wherein the extending portion of the contact structure is in direct contact with the refill material.

12. The method for forming the semiconductor device structure as claimed in claim 7, wherein the first semiconductor layers have different lengths.

13. The method for forming the semiconductor device structure as claimed in claim 7, wherein a bottom portion of the gate structure over the isolation material is narrower than the gate structure wrapped around the second semiconductor layers.

14. The method for forming the semiconductor device structure as claimed in claim 7, further comprising:
removing the fin structures and the isolation material exposed by the spacer layers and the dummy gate structure,
wherein a ratio of a remaining height of the isolation material above a bottom surface of the first semiconductor layers and a height of the first semiconductor layers and second semiconductor layers above the bottom surface of the first semiconductor layers is in a range of about 0.5 to about 1.

15. A semiconductor device structure, comprising:
fin structures with nanostructures formed over a substrate;
an isolation material surrounding the fin structures;
a gate structure surrounding the nanostructures and longitudinally oriented along a first direction;
spacer layers formed over opposite sides of the gate structure;
source/drain epitaxial structures formed at opposite sides of the gate structures in a second direction different from the first direction;
a gate isolation structure formed between the fin structures; and
contact structures formed over the source/drain epitaxial structures,
wherein bottommost surface of the spacer layers is higher than a bottommost surface of the topmost nanostructures in a cross-sectional view over the spacer layers along the first direction.

16. The semiconductor device structure as claimed in claim 15, further comprising:
a refill material formed between the spacer layers and the isolation material.

17. The semiconductor device structure as claimed in claim 16, further comprising:
an etch stop layer formed over the source/drain epitaxial structures,
wherein the isolation material and the etch stop layer are separated by the refill material.

18. The semiconductor device structure as claimed in claim 16, wherein the gate isolation structure is formed over the refill material.

19. The semiconductor device structure as claimed in claim 15, wherein a lower portion of the gate structure surrounding the nanostructures is wider than an upper portion of the gate structure surrounding the nanostructures.

20. The semiconductor device structure as claimed in claim 15, wherein the isolation material between the source/drain epitaxial structures has a flat top surface.
